(19) United States
(12) Patent Application Publication
(10) Pub. No.: US 2026/0047086 A1
(43) Pub. Date: Feb. 12, 2026

(54) High-Isolation P-Substrate on RF PMOS

(71) Applicant: Taiwan Semiconductor Manufacturing Company, Ltd., Hsinchu (TW)

(72) Inventors: Hui Wen Liu, Hsinchu City (TW); Po-Hsun Chu, Hsinchu City (TW); Chien-Ying Chen, Hsinchu City (TW); Chia-En Huang, Hsinchu City (TW); Jung-Hsuan Chen, Hsinchu City (TW); Ting-Wei Chiang, Hsinchu City (TW)

(73) Assignee: Taiwan Semiconductor Manufacturing Company, Ltd., Hsinchu (TW)

(21) Appl. No.: 18/968,841

(22) Filed: Dec. 4, 2024

Related U.S. Application Data
(60) Provisional application No. 63/680,895, filed on Aug. 8, 2024.

(51) Int. Cl. H10B 20/00; H01L 23/50

(52) U.S. Cl. CPC H10B 20/367; H01L 23/50

(57) ABSTRACT

A memory device includes a memory cells, each of which is configured to store one or more data bits; a first interconnect structure operatively configured as a bit line and coupled to each of the plurality of memory cells, the first interconnect structure extending along a first lateral direction; and a second interconnect structure operatively configured to carry a supply voltage and coupled to each of the plurality of memory cells, the second interconnect structure extending along the first lateral direction. The one or more data bits stored by a first one of the plurality of memory cells correspond to a first logic state, the first memory cell includes a first epitaxial structure with a nearly vertical sidewall in direct contact with a first dielectric structure, and the first epitaxial structure and the first dielectric structure are both coupled to either the first interconnect structure or the second interconnect structure.

### CROSS-REFERENCE TO RELATED APPLICATION

This application claims priority to and the benefit of U.S. Provisional Application No. 63/680,895, filed Aug. 8, 2024, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a read only memory (ROM) cell, in accordance with some embodiments.

FIG. 2 illustrates a layout for forming a memory array including a plural number of ROM cells, in accordance with some embodiments.

FIG. 3 illustrates a hybrid cross-sectional view of the memory array formed by the layout of FIG. 2, in accordance with some embodiments.

FIG. 4 and FIG. 5 each illustrate a cross-sectional view of the memory array formed by the layout of FIG. 2, in accordance with some embodiments.

FIG. 6 illustrates a layout for forming a memory array including a plural number of ROM cells, in accordance with some embodiments.

FIG. 7 illustrates a hybrid cross-sectional view of the memory array formed by the layout of FIG. 6, in accordance with some embodiments.

FIG. 8 and FIG. 9 each illustrate a cross-sectional view of the memory array formed by the layout of FIG. 6, in accordance with some embodiments.

FIG. 10 illustrates a cross-sectional view of a memory array including a plural number of ROM cells each presenting a respective logic state, in accordance with some embodiments.

FIG. 11 illustrates a layout for forming a memory array including a plural number of ROM cells, in accordance with some embodiments.

FIG. 12 illustrates a layout for forming a memory array including a plural number of ROM cells, in accordance with some embodiments.

FIG. 13 illustrates a layout for forming a memory array including a plural number of ROM cells, in accordance with some embodiments.

FIG. 14 illustrates a hybrid cross-sectional view of the memory array formed by the layout of FIG. 13, in accordance with some embodiments.

FIG. 15 and FIG. 16 each illustrate a cross-sectional view of the memory array formed by the layout of FIG. 13, in accordance with some embodiments.

FIG. 17 illustrates a layout for forming a memory array including a plural number of ROM cells, in accordance with some embodiments.

FIG. 18 illustrates a hybrid cross-sectional view of the memory array formed by the layout of FIG. 17, in accordance with some embodiments.

FIG. 19 and FIG. 20 each illustrate a cross-sectional view of the memory array formed by the layout of FIG. 17, in accordance with some embodiments.

FIG. 21 illustrates a cross-sectional view of a memory array including a plural number of ROM cells each presenting a respective logic state, in accordance with some embodiments.

FIG. 22 illustrates a layout for forming a memory array including a plural number of ROM cells, in accordance with some embodiments.

FIG. 23 illustrates a layout for forming a memory array including a plural number of ROM cells, in accordance with some embodiments.

FIG. 24 illustrates a layout for forming a memory array including a plural number of ROM cells, in accordance with some embodiments.

FIG. 25 illustrates a hybrid cross-sectional view of the memory array formed by the layout of FIG. 24, in accordance with some embodiments.

FIG. 26 and FIG. 27 each illustrate a cross-sectional view of the memory array formed by the layout of FIG. 24, in accordance with some embodiments.

FIG. 28 illustrates a layout for forming a memory array including a plural number of ROM cells, in accordance with some embodiments.

FIG. 29 illustrates a hybrid cross-sectional view of the memory array formed by the layout of FIG. 28, in accordance with some embodiments.

FIG. 30 and FIG. 31 each illustrate a cross-sectional view of the memory array formed by the layout of FIG. 28, in accordance with some embodiments.

FIG. 32 illustrates a cross-sectional view of a memory array including a plural number of ROM cells each presenting a respective logic state, in accordance with some embodiments.

FIG. 33 illustrates a layout for forming a memory array including a plural number of ROM cells, in accordance with some embodiments.

FIG. 34 illustrates a layout for forming a memory array including a plural number of ROM cells, in accordance with some embodiments.

FIG. 35 illustrates a cross-sectional view of a memory array including a plural number of ROM cells each presenting a respective logic state, in accordance with some embodiments.

FIG. 36 illustrates a cross-sectional view of a memory array including a plural number of ROM cells each presenting a respective logic state, in accordance with some embodiments.

FIG. 37 illustrates a cross-sectional view of a memory array including a plural number of ROM cells each presenting a respective logic state, in accordance with some embodiments.

FIG. 38 illustrates a cross-sectional view of a memory array including a plural number of ROM cells each presenting a respective logic state, in accordance with some embodiments.

FIG. 39 illustrates a cross-sectional view of a memory array including a plural number of ROM cells each presenting a respective logic state, in accordance with some embodiments.

FIG. 40 illustrates a cross-sectional view of a memory array including a plural number of ROM cells each presenting a respective logic state, in accordance with some embodiments.

FIG. 41 illustrates a flow chart of a method for forming a memory array including a plural number of ROM cells, each of which presents a respective logic state with a tailored epitaxial structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Read only memory (ROM) arrays are semiconductor memory chip arrays with data permanently stored in the array. ROM arrays are made up of a number of ROM cells, each ROM cell typically including a transistor in an “on” or “off” state. Each ROM cell is configured to store a (e.g., binary) data bit reflecting that on or off state. To program a ROM cell to an on state or an off state, it generally depends on whether an interconnect structure carrying a ground voltage (e.g., VSS) or configured as a bit line (BL) is electrically coupled to an active region (e.g., a source/drain region) of the corresponding transistor. As such, even with a plural number of ROM cells, a ROM array can only present two different logic states, e.g., through coupling to the BL/VSS or decoupling from the BL/VSS. Given a certain area to form a ROM array, an amount of data information that can be stored by the existing ROM array is limited. Thus, the existing ROM devices/arrays have not been entirely satisfactory in certain aspects.

The present disclosure provides various embodiments of a memory device (e.g., a memory array) including a plural number of ROM cells, each of which can include at least one transistor with its source/drain region or epitaxial structure having a “tailored” width along a lateral direction perpendicular to a channel length direction of the transistor. The epitaxial structures of the ROM cells across the memory array can be tailored to have more than two widths, which causes the ROM cells of the memory array to present more than two current levels, in various embodiments. As such, the ROM cells of the memory array, as disclosed herein, can present more than two logic states. For example, four different widths of the epitaxial structures can be configured, which results in four current levels flowing through respective ROM cells. Accordingly, the memory array can present four different logic states, e.g., [00], [01], [10], and [11], corresponding to those four current levels, respectively. In some embodiments, the width of the epitaxial structure can be tailored through one or more anisotropic etching processes, and the etched portion can be replaced with a dielectric structure having a width inversely proportional to the width of the corresponding epitaxial structure. As a non-limiting example, for a first one of the ROM cells presenting logic [00], one of its epitaxial structures can be completely replaced with a dielectric structure; for a second one of the ROMs presenting logic [01], ⅔ of one of its epitaxial structures can be replaced with another dielectric structure; for a third one of the ROMs presenting logic [10], ⅓ of one of its epitaxial structures can be replaced with yet another dielectric structure; and for a fourth one of the ROMs presenting logic [11], one of its epitaxial structures can retain (i.e., without being replaced by any dielectric structure).

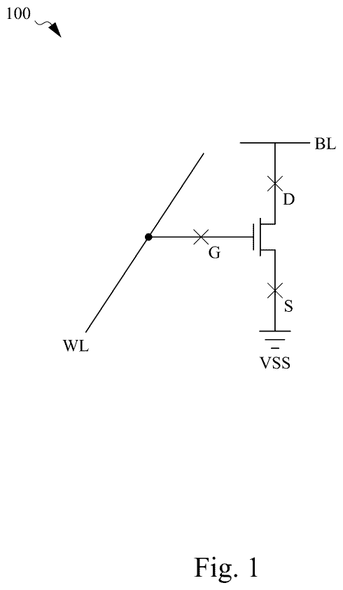

FIG. 1 illustrates an example circuit diagram of a single ROM cell 100, in accordance with some embodiments. A plural number of such ROM cells 100 can be arranged as a (e.g., two-dimensional) array having a plural number of rows and a plural number of columns, each of the ROM cells disposed at an intersection of a corresponding row and a corresponding column. Although the ROM cell 100 shown in FIG. 1 includes one transistor, it should be understood that the circuit diagram of FIG. 1 is provided for illustrative purposes and is not intended to limit the scope of the present disclosure. Accordingly, the ROM cell 100 shown in FIG. 1 can include any of various other components, while remaining within the scope of the present disclosure.

As shown, the ROM cell 100 includes one transistor 110 having a gate terminal, a first source/drain terminal, and a second source/drain terminal. The gate terminal is connected to a word line (WL), the drain terminal is connected to a bit line (BL), and the source terminal is connected to a supply voltage, e.g., a ground voltage (VSS). According to some embodiments of the present disclosure, either the drain terminal (formed as an epitaxial structure) or the source terminal (formed as another epitaxial structure) of the ROM cell 100 can have a tailor width, e.g., one of four different widths. Instead of selectively coupling to either the BL or VSS like the existing ROM cells, the ROM cell 100 can present a logic state based on its conductive current which is in turn determined according to the width of the epitaxial structure. In the above example where the ROM cell can have its source or drain terminal with one of four widths, each of the ROM cell 100s can be programmed (e.g., formed) with two data bits to present one of four logic states, logic [00], logic [01], logic [10], and logic [11].

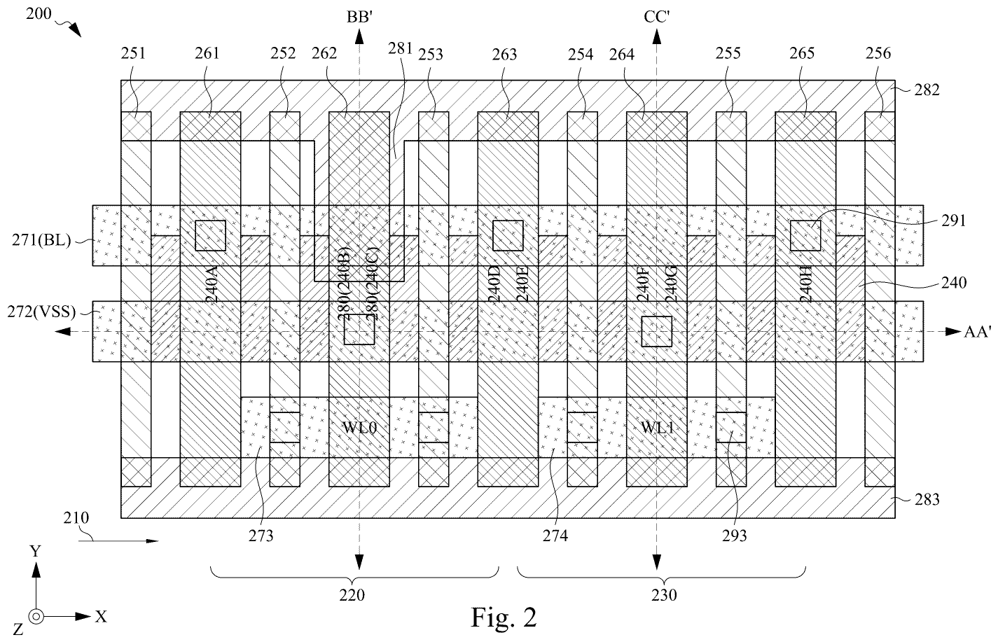

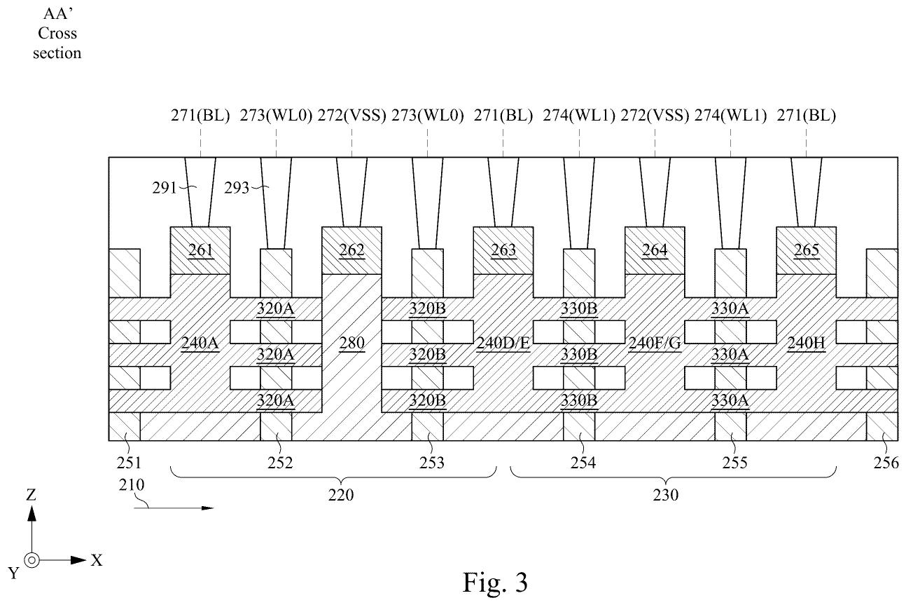

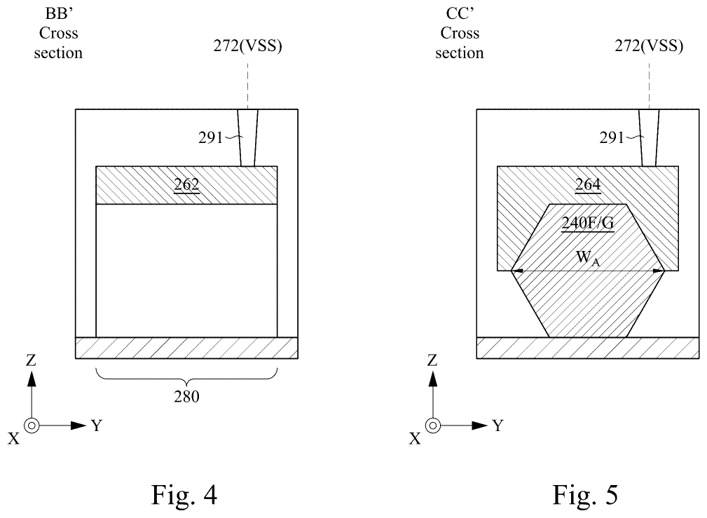

FIG. 2 illustrates an example layout 200 configured to form (or program) a memory array 210 including ROM cells, 220 and 230, that present a first logic state and a second logic state, respectively, in accordance with some embodiments. Further, FIG. 3 illustrates a hybrid cross-sectional view of the memory array 210, FIG. 4 illustrates a cross-sectional view of the ROM cell 220, and FIG. 5 illustrates a cross-sectional view of the ROM cell 230. As disclosed herein, the term “hybrid cross-sectional view” refers to a combination of multiple cross-sectional views cut along the same direction and overlapped with each other. It should be understood that the layout 200 of FIG. 2 and the corresponding cross-sectional views of FIGS. 3-5 are provided merely for illustrative purposes, and are not intended to limit the scope of the present disclosure.

Referring to FIG. 2, the layout 200 includes patterns for forming an active region 240, gate structures 251, 252, 253, 254, 255, and 256, respectively. It should be understood that the layout 200 can include any number of other patterns to form respective active regions or gate structures, while remaining within the scope of present disclosure. In some embodiments, the active region 240 can extend along a first lateral direction (e.g., the X-direction), and the gate structures 251 to 256 can each extend along a second lateral direction (e.g., the Y-direction) perpendicular to the first lateral direction. The gate structures 251 to 256 can each traverse the active region 240. The gate structures 251 to 256 can each correspond to an active (e.g., metal) gate structure. For example, the gate structures 251 to 256 can define respective footprints of several later formed metal gate structures, each of which can include a gate dielectric (e.g., a high-k material) and a gate metal (e.g., one or more work function metal materials).

In some embodiments, the ROM cells of the memory array 210 (e.g., 220, 230) may each be formed as a gate-all-around (GAA) transistor. However, the ROM cells of the memory array (formed by the layout 200) can be formed as any of various other transistor structure while remaining within the scope of the present disclosure. In the example of GAA transistor structures, the active region 240 can be formed as a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by the gate structures 251 to 256 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., wraps around) the remaining portions of the semiconductor structures can be configured as a gate terminal of the transistor.

In FIG. 2, the active region 240, together with the gate structures 252 and 253, can form the ROM cell 220 with a two-transistor (2T) configuration. For example, the portion of the active region 240 overlaid by the gate structure 252 may include a number of first nanostructures vertically separated from each other, which can collectively function as the channel of a first sub-transistor, and the portion of the active region 240 overlaid by the gate structure 253 may include a number of second nanostructures vertically separated from each other, which can collectively function as the channel of a second sub-transistor. These two sub-transistors can be coupled to each other in parallel (e.g., respective gate terminals, first source/drain terminals, and second source/drain terminals tied together), thereby forming the ROM cell 220 in the 2T configuration, in some embodiments.

Further, the portions of the active region 240 that are disposed on opposite sides of each of the gate structures 252 and 253 are replaced with epitaxial structures, respectively. Such epitaxial structures can function as source/drain terminals of the sub-transistors. For example, the gate structure 252 can function as a gate terminal of the first sub-transistor; the gate structure 253 can function as a gate terminal of the second sub-transistor; epitaxial structures (240A and 240B) formed on the opposite sides of the gate structure 252 can function as a first source/drain terminal and second source/drain terminal of the first sub-transistor, respectively; epitaxial structures (240C and 240D) formed on the opposite sides of the gate structure 253 can function as a second source/drain terminal and first source/drain terminal of the second sub-transistor, respectively. The second source/drain terminal (e.g., 240B) of the first sub-transistor and the second source/drain terminal (e.g., 240C) of the second sub-transistor are connected to (merged with) each other.

Similarly, the active region 240, together with the gate structures 254 and 255, can form the ROM cell 230 in the same 2T configuration, e.g., with two sub-transistors coupled to each other in parallel. A first one of the two sub-transistors is formed by the gate structure 255, and epitaxial structures 240H and 240G that serve as its first and second source/drain terminals, respectively. A second one of the two sub-transistor is formed by the gate structure 254, and epitaxial structures 240E and 240F that serve as its first and second source/drain terminals, respectively. The second source/drain terminal (e.g., 240F) of the second sub-transistor and the second source/drain terminal (e.g., 240G) of the first sub-transistor are connected to (merged with) each other. As such, it should be appreciated that the respective components of the ROM cell 220 and the ROM cell 230 are symmetrical to each other with respect to a virtual axis interposed between the gate structures 253 and 254.

The layout 200 further includes patterns for forming source/drain contact structures (sometimes referred to as MDs) 261, 262, 263, 264, and 265, and interconnect structures 271, 272, 273, and 274, respectively. It should be understood that the layout 200 can include any number of other patterns to form respective MDs or interconnect structures, while remaining within the scope of present disclosure. In some embodiments, the MDs 261 to 265 can each extend along the Y-direction, and the interconnect structures 271 to 274 can each extend along the X-direction. The MDs 261 to 265 can each be in electrical contact with a corresponding epitaxial structure (the source/drain terminal of a transistor or sub-transistor). The interconnect structures 271 to 274 can each be electrically coupled to one or more corresponding gate structures or one or more corresponding MDs.

In some embodiments, after forming the epitaxial structures 240A to 240H and prior to forming the MDs 261 to 265, at least a portion of the epitaxial structures 240B-C can be replaced with a vertical dielectric structure 280 (which can be better seen in the cross-sectional views of FIGS. 3-4), while other epitaxial structures 240A and 240D-H may remain substantially intact. For example, a whole of the epitaxial structures 240B-C may be replaced with the dielectric structure 280. This can cause the channel of the first sub-transistor of the ROM cell 220 (e.g., the nanostructures overlaid by the gate structure 252) to have one of its ends to directly contact the dielectric structure 280, and the channel of the second sub-transistor of the ROM cell 220 (e.g., the nanostructures overlaid by the gate structure 253) to have one of its ends to directly contact the dielectric structure 280.

Such a removal process and a replacement process can be performed based on a cut pattern 281 included in the layout 200. For example, the cut pattern 281 can extend along the Y-direction and be formed wider than or equal to the corresponding MD 262 in the X-direction. Following the cut pattern 281, a portion of the epitaxial structures 240B-C can be removed (e.g., anisotropically etched) and the removed portion can be filled with a dielectric material to form the dielectric structure 280. As such, instead of electrically coupled to an epitaxial structure, the MD 262 is (e.g., physically) coupled to dielectric structure 280, causing any conductive structure formed above (and electrically connected to) the MD 262 to be electrically isolated from an epitaxial structure. Stated another way, the MD 262 is electrically isolated from one of the source/drain terminals of the ROM cell 220 (or the second source/drain terminals of the first and second sub-transistors of the ROM cell 220). The cut pattern 281 can be coupled to one or more other cut patterns 282 and 283 that extend along the X-direction, as shown in FIG. 2. The cut patterns 282 and 283 can be configured to cut one or more of the gate structures 251 to 256 (into multiple segments), in some embodiments.

The interconnect structures 271 to 274 can each be formed as a metal track in one of plural metallization layers disposed over the frontside surface of the substrate, or over the MDs 261-265 and the gate structures 251-256. Each of the metallization layers can include (e.g., embed) a plural number of metal tracks in one or more dielectric layers (e.g., formed of an oxide material or a low-k dielectric material). In some embodiments, the interconnect structures 271 to 274 may be formed in a bottommost one of the metallization layers. Such a bottommost metallization layer is sometimes referred to as an M0 layer, and accordingly, a metal track included in the M0 layer is sometimes referred to as an M0 track. Further, in some embodiments, the M0 track 271 can operatively serve as a bit line (BL) or a portion of the BL for the memory array 210, the M0 track 272 can operatively serve as a power rail carrying a ground voltage (VSS) or a portion of the power rail for the memory array 210, the M0 track 273 can operatively serve as a word line (WL0) or a portion of the WL0 for the memory array 210, and the M0 track 274 can operatively serve as another word line (WL1) or a portion of the WL1 for the memory array 210.

The M0 track 271 (BL) can extend along the X-direction to couple to at least the ROM cells 220 and 230. For example, the M0 track 271 is coupled to the MDs 261, 263, and 265 through multiple via structures 291, respectively. The MDs 261 and 263 are electrically coupled to one of the source/drain terminals of the ROM cell 220 (e.g., the epitaxial structures 240A and 240D), and the MDs 263 and 265 are electrically coupled to one of the source/drain terminals of the ROM cell 230 (e.g., the epitaxial structures 240E and 240H).

The M0 track 272 (VSS) can also extend along the X-direction to couple to at least the ROM cells 220 and 230. For example, the M0 track 272 is coupled to the MDs 262 and 264 through multiple via structures 291, respectively. The MD 262 is physically coupled to but electrically isolated from the other source/drain terminal of the ROM cell 220 as the portion of the epitaxial structures 240B-C that serves as the other source/drain terminal of the ROM cell 220 has been replaced with the dielectric structure 280, and the MD 264 is electrically coupled to the other source/drain terminal of the ROM cell 230 (e.g., the epitaxial structures 240F and 240G which can be merged).

The M0 track 273 (WL0) can also extend along the X-direction to couple to the ROM cell 220. For example, the M0 track 273 is coupled to the gate structures 252 and 253 through multiple via structures 293, respectively. The gate structures 252 and 253 can collectively serve as the gate terminal of the ROM cell 220. Similarly, the M0 track 274 (WL1) can also extend along the X-direction to couple to the ROM cell 230. For example, the M0 track 274 is coupled to the gate structures 254 and 255 through multiple via structures 293, respectively. The gate structures 254 and 255 can collectively serve as the gate terminal of the ROM cell 230.

Referring next to FIG. 3, the hybrid cross-sectional view includes a plural number of cross-sectional views of the memory array 210, each of which is cut along line AA′ (indicated in FIG. 2). As shown in FIG. 3, the epitaxial structures 240B-C are replaced by the dielectric structure 280, which causes one of the source/drain terminals of the first sub-transistor and one of the source/drain terminals of the second sub-transistor of the ROM cell 220 to be electrically isolated from the interconnect structure 272 (VSS). The channel of the first sub-transistor (e.g., nanostructures 320A overlaid or wrapped by the gate structure 252) has one end in direct contact with the dielectric structure 280, with the other end electrically coupled to the epitaxial structure 240A; and the channel of the second sub-transistor (e.g., nanostructures 320B overlaid or wrapped by the gate structure 253) has one end in direct contact with the dielectric structure 280, with the other end electrically coupled to the epitaxial structures 240D-E. Equivalently, the ROM cell 220 has one of its source/drain terminals disconnected from the interconnect structure 272 (VSS) and the other source/drain terminal coupled to the interconnect structure 271 (BL). As a result, the ROM cell 220 may conduct a first current, a level of which is relatively low or close to zero.

FIG. 4 further illustrates another cross-sectional view of the memory array 210 cut along line BB′ (indicated in FIG. 2). For example, the cross-sectional view of FIG. 4 is cut along the dielectric structure 280. As shown, the dielectric structure 280 may have a whole of its top surface in contact with a bottom surface of the MD 262, while a top surface of the MD 262 is electrically connected to the interconnect structure 272 (VSS) through one of the via structures 291. In some embodiments, the dielectric structure 280 may have its sidewalls each in contact with no epitaxial structure. Such sidewalls of the dielectric structure 280 can face the Y-direction. Stated another way, the MD 262 has no portion in contact with an epitaxial structure.

Referring again to FIG. 3, the epitaxial structures 240F-G retain, which causes one of the source/drain terminals of the first sub-transistor and one of the source/drain terminals of the second sub-transistor of the ROM cell 230 to be electrically couped to the interconnect structure 272 (VSS). The channel of the second sub-transistor (e.g., nanostructures 330A overlaid or wrapped by the gate structure 254) has one end electrically coupled to the epitaxial structures 240F-G, with the other end electrically coupled to the epitaxial structures 240D-E; and the channel of the first sub-transistor (e.g., nanostructures 330B overlaid or wrapped by the gate structure 255) has one end electrically coupled to the epitaxial structures 240F-G, with the other end electrically coupled to the epitaxial structure 240H. Equivalently, the ROM cell 230 has one of its source/drain terminals coupled to the interconnect structure 272 (VSS) and the other source/drain terminal coupled to the interconnect structure 271 (BL). As a result, the ROM cell 230 may conduct a second current, a level of which is relatively high.

FIG. 5 further another cross-sectional view of the memory array 210 cut along line CC′ (indicated in FIG. 2). For example, the cross-sectional view of FIG. 5 is cut along the epitaxial structures 240F-G. As shown, the epitaxial structures 240F-G may have a whole of its top surface in contact with a bottom surface of the MD 264, and a top surface of the MD 264 is electrically connected to the interconnect structure 272 (VSS) through one of the via structures 291. In some embodiments, a whole of the epitaxial structures 240F-G is electrically coupled to the MD 264. Stated another way, the MID 264 has a portion with a width along the Y-direction (WA) in contact with the epitaxial structures 240F-G, or the epitaxial structures 240F-G have a width along the Y-direction (WA) in contact with the MD 264.

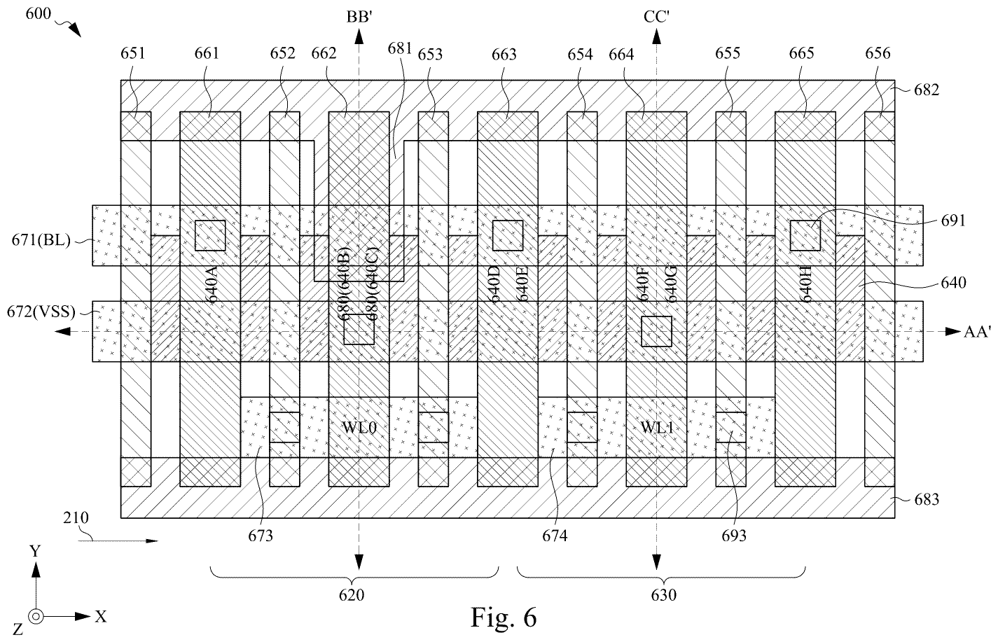

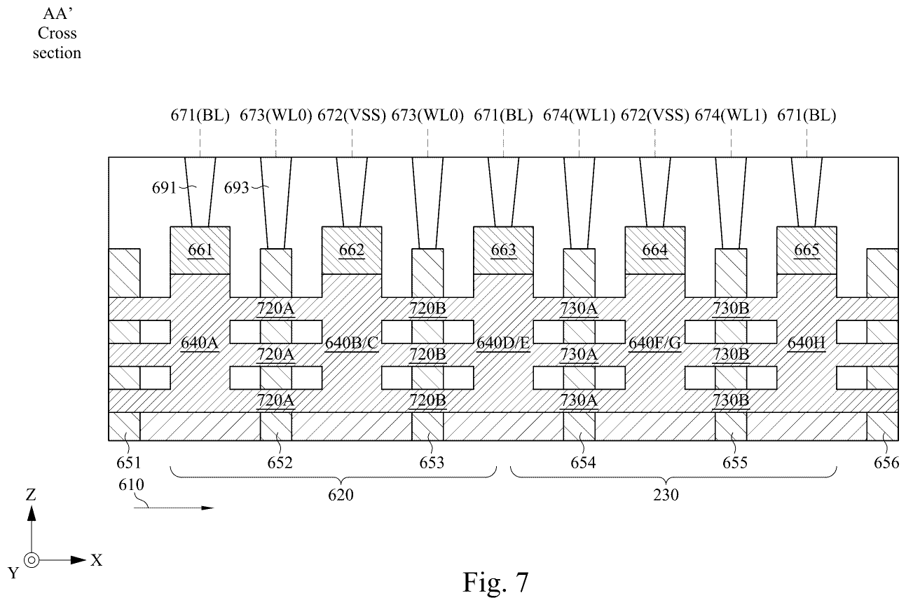

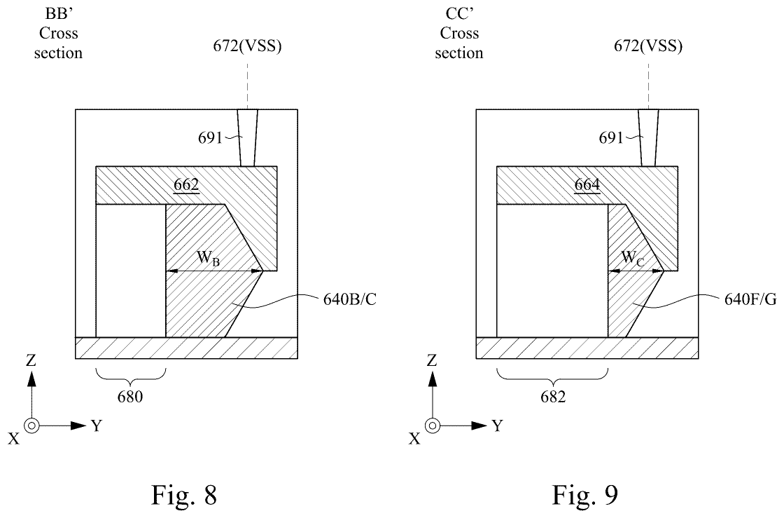

FIG. 6 illustrates an example layout 600 configured to form (or program) a memory array 610 including ROM cells, 620 and 630, that present a first logic state and a second logic state, respectively, in accordance with some embodiments. Further, FIG. 7 illustrates a hybrid cross-sectional view of the memory array 610, FIG. 8 illustrates a cross-sectional view of the ROM cell 620, and FIG. 9 illustrates a cross-sectional view of the ROM cell 630. It should be understood that the layout 600 of FIG. 6 and the corresponding cross-sectional views of FIGS. 7-9 are provided merely for illustrative purposes, and are not intended to limit the scope of the present disclosure.

Referring to FIG. 6, the layout 600 includes patterns for forming an active region 640, gate structures 651, 652, 653, 654, 655, and 656, respectively. It should be understood that the layout 600 can include any number of other patterns to form respective active regions or gate structures, while remaining within the scope of present disclosure. In some embodiments, the active region 640 can extend along a first lateral direction (e.g., the X-direction), and the gate structures 651 to 656 can each extend along a second lateral direction (e.g., the Y-direction) perpendicular to the first lateral direction. The gate structures 651 to 656 can each traverse the active region 640. The gate structures 651 to 656 can each correspond to an active (e.g., metal) gate structure. For example, the gate structures 651 to 656 can define respective footprints of several later formed metal gate structures, each of which can include a gate dielectric (e.g., a high-k material) and a gate metal (e.g., one or more work function metal materials).

In some embodiments, the ROM cells of the memory array 610 (e.g., 620, 630) may each be formed as a gate-all-around (GAA) transistor. However, the ROM cells of the memory array (formed by the layout 600) can be formed as any of various other transistor structure while remaining within the scope of the present disclosure. In the example of GAA transistor structures, the active region 640 can be formed as a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by the gate structures 651 to 656 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., wraps around) the remaining portions of the semiconductor structures can be configured as a gate terminal of the transistor.

In FIG. 6, the active region 640, together with the gate structures 652 and 653, can form the ROM cell 620 with the above-described 2T configuration. For example, the portion of the active region 640 overlaid by the gate structure 652 may include a number of first nanostructures vertically separated from each other, which can collectively function as the channel of a first sub-transistor, and the portion of the active region 640 overlaid by the gate structure 653 may include a number of second nanostructures vertically separated from each other, which can collectively function as the channel of a second sub-transistor. These two sub-transistors can be coupled to each other in parallel (e.g., respective gate terminals, first source/drain terminals, and second source/drain terminals tied together), thereby forming the ROM cell 620 in the 2T configuration, in some embodiments.

Further, the portions of the active region 640 that are disposed on opposite sides of each of the gate structures 652 and 653 are replaced with epitaxial structures, respectively. Such epitaxial structures can function as source/drain terminals of the sub-transistors. For example, the gate structure 652 can function as a gate terminal of the first sub-transistor; the gate structure 653 can function as a gate terminal of the second sub-transistor; epitaxial structures (640A and 640B) formed on the opposite sides of the gate structure 652 can function as a first source/drain terminal and second source/drain terminal of the first sub-transistor, respectively; epitaxial structures (640C and 640D) formed on the opposite sides of the gate structure 653 can function as a second source/drain terminal and first source/drain terminal of the second sub-transistor, respectively. The second source/drain terminal (e.g., 640B) of the first sub-transistor and the second source/drain terminal (e.g., 640C) of the second sub-transistor are connected to (merged with) each other.

Similarly, the active region 640, together with the gate structures 654 and 655, can form the ROM cell 630 in the same 2T configuration, e.g., with two sub-transistors coupled to each other in parallel. A first one of the two sub-transistors is formed by the gate structure 655, and epitaxial structures 640H and 640G that serve as its first and second source/drain terminals, respectively. A second one of the two sub-transistor is formed by the gate structure 654, and epitaxial structures 640E and 640F that serve as its first and second source/drain terminals, respectively. The second source/drain terminal (e.g., 640G) of the second sub-transistor and the second source/drain terminal (e.g., 640F) of the first sub-transistor are connected to (merged with) each other. As such, it should be appreciated that the respective components of the ROM cell 620 and the ROM cell 630 are symmetrical to each other with respect to a virtual axis interposed between the gate structures 653 and 654.

The layout 600 further includes patterns for forming source/drain contact structures (sometimes referred to as MDs) 661, 662, 663, 664, and 665, and interconnect structures 671, 672, 673, and 674, respectively. It should be understood that the layout 600 can include any number of other patterns to form respective MDs or interconnect structures, while remaining within the scope of present disclosure. In some embodiments, the MDs 661 to 665 can each extend along the Y-direction, and the interconnect structures 671 to 674 can each extend along the X-direction. The MDs 661 to 665 can each be in electrical contact with a corresponding epitaxial structure (the source/drain terminal of a transistor or sub-transistor). The interconnect structures 671 to 674 can each be electrically coupled to one or more corresponding gate structures or one or more corresponding MDs.

In some embodiments, after forming the epitaxial structures 640A to 640H and prior to forming the MDs 661 to 665, at least a portion of the epitaxial structures 640B-C can be replaced with a vertical dielectric structure 680 (which can be better seen in the cross-sectional views of FIGS. 7 and 8) and at least a portion of the epitaxial structures 640F-G can be replaced with a vertical dielectric structure 682 (which can be better seen in the cross-sectional views of FIGS. 7 and 9), while other epitaxial structures 240A, 240D-E, and 240H may remain substantially intact.

For example, ⅓ of the epitaxial structures 640B-C may be replaced with the dielectric structure 680. This can cause the channel of the first sub-transistor of the ROM cell 620 (e.g., the nanostructures overlaid by the gate structure 652) to have one of its ends to directly contact a combination of the dielectric structure 680 and the remaining portion of the epitaxial structures 640B-C (e.g., ⅔ of the epitaxial structures 640B-C), and the channel of the second sub-transistor of the ROM cell 620 (e.g., the nanostructures overlaid by the gate structure 653) to have one of its ends to directly contact a combination of the dielectric structure 680 and the remaining portion of the epitaxial structures 640B-C (e.g., ⅔ of the epitaxial structures 640B-C).

In another example, ⅔ of the epitaxial structures 640F-G may be replaced with the dielectric structure 682. This can cause the channel of the first sub-transistor of the ROM cell 630 (e.g., the nanostructures overlaid by the gate structure 654) to have one of its ends to directly contact a combination of the dielectric structure 682 and the remaining portion of the epitaxial structures 640F-G (e.g., ⅓ of the epitaxial structures 640F-G), and the channel of the second sub-transistor of the ROM cell 630 (e.g., the nanostructures overlaid by the gate structure 655) to have one of its ends to directly contact a combination of the dielectric structure 682 and the remaining portion of the epitaxial structures 640F-G (e.g., ⅓ of the epitaxial structures 640F-G).

Such a removal process and a replacement process can be performed based on cut patterns 681 and 683 included in the layout 600. For example, the cut pattern 681 can extend along the Y-direction and be formed wider than or equal to the corresponding MD 662 in the X-direction. Further, the cut pattern 681 can overlay ⅓ of the epitaxial structures 640B-C. For another example, the cut pattern 683 can extend along the Y-direction and be formed wider than or equal to the corresponding MD 664 in the X-direction. Further, the cut pattern 683 can overlay ⅔ of the epitaxial structures 640F-G. Following the cut pattern 681, ⅓ of the epitaxial structures 640B-C can be removed (e.g., anisotropically etched) and the removed portion can be filled with a dielectric material to form the dielectric structure 680. Similarly, following the cut pattern 683, ⅔ of the epitaxial structures 640F-G can be removed (e.g., anisotropically etched) and the removed portion can be filled with a dielectric material to form the dielectric structure 682.

As such, the MD 662 is (e.g., physically) coupled to the dielectric structure 680 and the ⅔ of the epitaxial structures 640B-C combined, causing any conductive structure formed above (and electrically connected to) the MD 662 to be electrically coupled to the ⅔ of the epitaxial structures 640B-C. Stated another way, the MD 662 is electrically connected to one of the source/drain terminals of the ROM cell 620 (or the second source/drain terminals of the first and second sub-transistors of the ROM cell 620). Similarly, the MD 664 is (e.g., physically) coupled to the dielectric structure 682 and the ½ of the epitaxial structures 640F-G combined, causing any conductive structure formed above (and electrically connected to) the MD 664 to be electrically coupled to the ⅓ of the epitaxial structures 640F-G. Stated another way, the MD 664 is electrically connected to one of the source/drain terminals of the ROM cell 630 (or the second source/drain terminals of the first and second sub-transistors of the ROM cell 630). The cut patterns 681 and 683 can each be coupled to one of other cut pattern 685 or 687 that extends along the X-direction, as shown in FIG. 6. For example, both of the cut patterns 681 and 683 have one of their ends connected to the cut pattern 685. The cut patterns 685 and 687 can be configured to cut one or more of the gate structures 651 to 656 (into multiple segments), in some embodiments.

The interconnect structures 671 to 674 can each be formed as a metal track in one of plural metallization layers disposed over the frontside surface of the substrate, or over the MDs 661-665 and the gate structures 651-656. Each of the metallization layers can include (e.g., embed) a plural number of metal tracks in one or more dielectric layers (e.g., formed of an oxide material or a low-k dielectric material). In some embodiments, the interconnect structures 671 to 674 may be formed in a bottommost one of the metallization layers. Such a bottommost metallization layer is sometimes referred to as an M0 layer, and accordingly, a metal track included in the M0 layer is sometimes referred to as an M0 track. Further, in some embodiments, the M0 track 671 can operatively serve as a bit line (BL) or a portion of the BL for the memory array 610, the M0 track 672 can operatively serve as a power rail carrying a ground voltage (VSS) or a portion of the power rail for the memory array 610, the M0 track 673 can operatively serve as a word line (WL0) or a portion of the WL0 for the memory array 610, and the M0 track 674 can operatively serve as another word line (WL1) or a portion of the WL1 for the memory array 610.

The M0 track 671 (BL) can extend along the X-direction to couple to at least the ROM cells 620 and 630. For example, the M0 track 671 is coupled to the MDs 661, 663, and 665 through multiple via structures 691, respectively. The MDs 661 and 663 are electrically coupled to one of the source/drain terminals of the ROM cell 620 (e.g., the epitaxial structures 640A and 640D which can be merged), and the MDs 663 and 665 are electrically coupled to one of the source/drain terminals of the ROM cell 630 (e.g., the epitaxial structures 640E and 640H which can be merged).

The M0 track 672 (VSS) can also extend along the X-direction to couple to at least the ROM cells 620 and 630. For example, the M0 track 672 is coupled to the MDs 662 and 664 through multiple via structures 691, respectively. The MD 662 is physically and electrically coupled to the other source/drain terminal of the ROM cell 620 (e.g., the remaining ⅔ of the epitaxial structures 640F and 640G), and the MD 664 is physically and electrically coupled to the other source/drain terminal of the ROM cell 630 (e.g., the remaining ⅓ of the epitaxial structures 640F and 640G).

The M0 track 673 (WL0) can also extend along the X-direction to couple to the ROM cell 620. For example, the M0 track 673 is coupled to the gate structures 652 and 653 through multiple via structures 693, respectively. The gate structures 652 and 653 can collectively serve as the gate terminal of the ROM cell 620. Similarly, the M0 track 674 (WL1) can also extend along the X-direction to couple to the ROM cell 630. For example, the M0 track 674 is coupled to the gate structures 654 and 655 through multiple via structures 693, respectively. The gate structures 654 and 655 can collectively serve as the gate terminal of the ROM cell 630.

Referring next to FIG. 7, the hybrid cross-sectional view includes a plural number of cross-sectional views of the memory array 610, each of which is cut along line AA′ (indicated in FIG. 6). As shown in FIG. 7, the epitaxial structures 640B-C still have a portion retained and in contact with the dielectric structure 680 (FIG. 8), which causes one of the source/drain terminals of the first sub-transistor and one of the source/drain terminals of the second sub-transistor of the ROM cell 620 to remain electrically coupled to the interconnect structure 672 (VSS). The channel of the first sub-transistor (e.g., nanostructures 720A overlaid or wrapped by the gate structure 652) has one end electrically coupled to the remaining portion of the epitaxial structures 640B-C and the dielectric structure 680, with the other end electrically coupled to the epitaxial structure 640A; and the channel of the second sub-transistor (e.g., nanostructures 720B overlaid or wrapped by the gate structure 653) has one end electrically coupled to the remaining portion of the epitaxial structures 640B-C and the dielectric structure 680, with the other end electrically coupled to the epitaxial structures 640D-E. Equivalently, the ROM cell 620 has one of its source/drain terminals, with a reduced portion (e.g., ⅔ of the original size), coupled to the interconnect structure 672 (VSS) and the other source/drain terminal coupled to the interconnect structure 671 (BL). As a result, the ROM cell 620 may conduct a third current, a level of which is higher than the first current (flowing through the ROM cell 220 of FIGS. 2-5) and lower than the second current (flowing through the ROM cell 230 of FIGS. 2-5).

FIG. 8 further illustrates another cross-sectional view of the memory array 610 cut along line BB′ (indicated in FIG. 6). For example, the cross-sectional view of FIG. 8 is cut along the dielectric structure 680 and the epitaxial structures 640B-C. As shown, the epitaxial structures 640B-C may have a sidewall (facing the Y-direction) in contact with the dielectric structure 680. Respective top surfaces of the dielectric structure 680 and the epitaxial structures 640B-C may be in contact with a bottom surface of the MD 662, while a top surface of the MD 662 is electrically connected to the interconnect structure 672 (VSS) through one of the via structures 691. In some embodiments, the MD 662 has a portion with a width along the Y-direction (WB) in contact with the (remaining) epitaxial structures 640B-C, or the (remaining) epitaxial structures 640B-C has a width along the Y-direction (WB) in contact with the MD 662.

Referring again to FIG. 6, the epitaxial structures 640F-G still has a portion retained and in contact with the dielectric structure 682 (FIG. 9), which causes one of the source/drain terminals of the first sub-transistor and one of the source/drain terminals of the second sub-transistor of the ROM cell 630 to remain electrically coupled to the interconnect structure 672 (VSS). The channel of the first sub-transistor (e.g., nanostructures 730B overlaid or wrapped by the gate structure 655) has one end electrically coupled to the remaining portion of the epitaxial structures 640F-G and the dielectric structure 682, with the other end electrically coupled to the epitaxial structure 640H; and the channel of the second sub-transistor (e.g., nanostructures 730A overlaid or wrapped by the gate structure 654) has one end electrically coupled to the remaining portion of the epitaxial structures 640F-G and the dielectric structure 682, with the other end electrically coupled to the epitaxial structures 640D-E. Equivalently, the ROM cell 630 has one of its source/drain terminals, with a reduced portion (e.g., ⅓ of the original size), coupled to the interconnect structure 672 (VSS) and the other source/drain terminal coupled to the interconnect structure 671 (BL). As a result, the ROM cell 630 may conduct a fourth current, a level of which is higher than the first current (flowing through the ROM cell 220 of FIGS. 2-5) and lower than the third current (flowing through the ROM cell 620 of FIGS. 6-9).

FIG. 9 further illustrates another cross-sectional view of the memory array 610 cut along line CC′ (indicated in FIG. 6). For example, the cross-sectional view of FIG. 9 is cut along the dielectric structure 682 and the epitaxial structures 640F-G. As shown, the epitaxial structures 640F-G may have a sidewall (facing the Y-direction) in contact with the dielectric structure 682. Respective top surfaces of the dielectric structure 682 and the epitaxial structures 640F-G may be in contact with a bottom surface of the MD 664, while a top surface of the MD 664 is electrically connected to the interconnect structure 672 (VSS) through one of the via structures 691. In some embodiments, the MD 664 has a portion with a width along the Y-direction (W_{C}) in contact with the (remaining) epitaxial structures 640F-G, or the (remaining) epitaxial structures 640F-G has a width along the Y-direction (W_{C}) in contact with the MD 664.

Based on the respective tailored sizes (e.g., widths in the Y-direction) of source/drain terminals which are implemented as epitaxial structures, ROM cells of a memory array can conduct different current levels, according to some embodiments of the present disclosure. These different current levels can cause the ROM cells to present respective logic states. For example, with four different widths of the epitaxial structures, the ROM cells of a memory array can present four logic states.

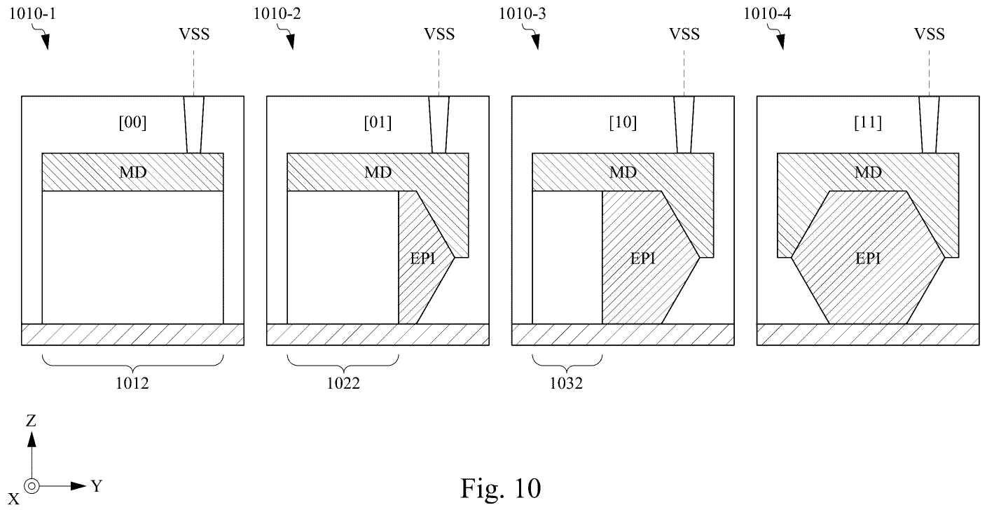

FIG. 10 illustrates four different logic states, [00], [01], [10], and [11], presented by ROM cells, 1010-1, 1010-2, 1010-3, and 1010-4, respectively, in accordance with some embodiments. As shown, the ROM cells 1010-1 to 1010-4 each have at least one of its epitaxial structures with a respective width in the Y-direction to contact an MD, which is further coupled to an interconnect structure configured as a power rail carrying a ground voltage (e.g., VSS). In some embodiments, by connecting different sizes of the epitaxial structures to VSS, the ROM cells 1010-1 to 1010-4 may be referred to as being programed through or coded on VSS.

For example, the ROM cell 1010-1 has one source/drain terminal replaced by a vertical dielectric structure 1012 and the other source/drain terminal retained, similar to the ROM cell 220 (FIG. 2); the ROM cell 1010-2 has one source/drain terminal with ⅔ replaced by a vertical dielectric structure 1022 and the other source/drain terminal retained, similar to the ROM cell 630 (FIG. 6); the ROM cell 1010-3 has one source/drain terminal with ⅓ replaced by a vertical dielectric structure 1032 and the other source/drain terminal retained, similar to the ROM cell 620 (FIG. 6); and the ROM cell 1010-4 has both of its source/drain terminals retained, similar to the ROM cell 230 (FIG. 2). As such, the ROM cells 1010-1, 1010-2, 1010-3, and 1010-4 can conduct four differentiable currents. For example, the ROM cell 1010-4 can conduct the highest current, the ROM cell 1010-3 can conduct the next highest current, the ROM cell 1010-2 can conduct the next lowest current, and the ROM cell 1010-1 can conduct the lowest current, causing the ROM cells 1010-4, 1010-3, 1010-2, and 1010-1 to present four different logic states, [11], [10], [01], and [00], respectively.

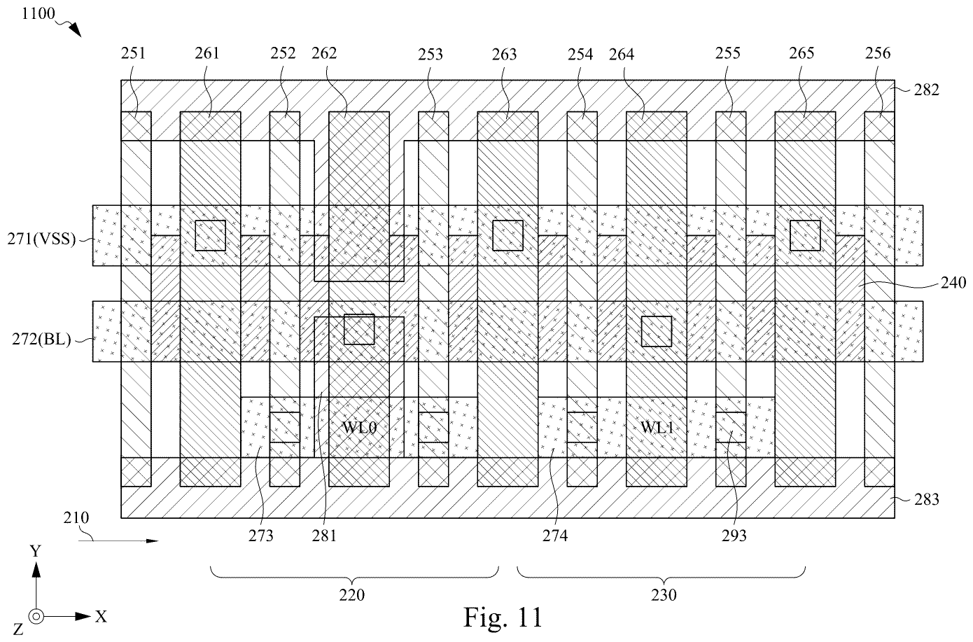

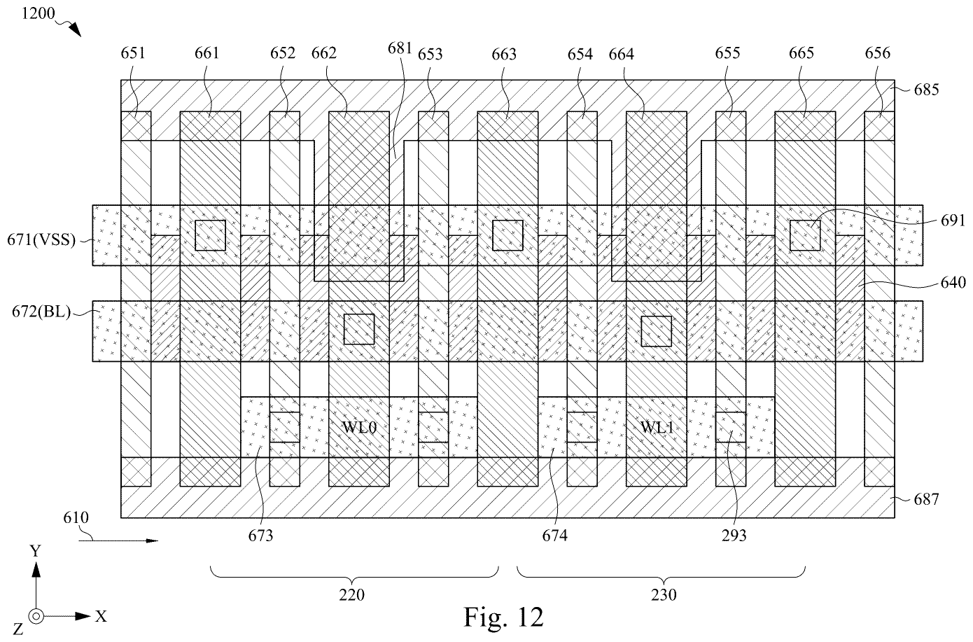

FIG. 11 and FIG. 12 illustrate example layouts 1100 and 1200, respectively, each of which is configured to form (or program) a memory array including two ROM cells that respectively present different logic states, in accordance with some embodiments. The layouts 1100 and 1200 are substantially similar to the layout 200 (FIG. 2) and layout 600 (FIG. 6), respectively, except that the functionalities of the interconnect structures 271 and 272 are switched in the layout 1100 and the functionalities of the interconnect structures 671 and 672 are switched in the layout 1200. Accordingly, the reference numerals of FIG. 2 and FIG. 6 are reused in the following discussion of FIG. 11 and FIG. 12, respectively.

Referring first to FIG. 11, the layout 1100, similar to the layout 200, includes the patterns for forming the active region 240, the gate structures 251 to 256, the MDs 261 to 265, and the M0 tracks 271 to 274, and the cut patterns 281 to 283. However, according to the layout 1100, the M0 tracks 271 and 272 are configured as the power rail carrying VSS and the BL, respectively. As such, the ROM cell 220 may have one of its source/drain terminals replaced by a dielectric structure which is electrically isolated from the BL, and the ROM cell 230 may have its source/drain terminals electrically coupled to the BL and VSS, respectively. The ROM cells 220 and 230, formed based on the layout 1100, may thus be referred to as being programed through or coded on BL.

Referring next to FIG. 12, the layout 1200, similar to the layout 600, includes the patterns for forming the active region 640, the gate structures 651 to 656, the MDs 661 to 665, and the M0 tracks 671 to 674, and the cut patterns 681 to 687. However, according to the layout 1200, the M0 tracks 671 and 672 are configured as the power rail carrying VSS and the BL, respectively. As such, the ROM cell 620 may have one of its source/drain terminals partially replaced by a dielectric structure and electrically coupled to the BL, and the ROM cell 630 may have its source/drain terminals partially replaced by another dielectric structure and electrically coupled to the BL. The ROM cells 620 and 630, formed based on the layout 1200, may thus be referred to as being programed through or coded on BL.

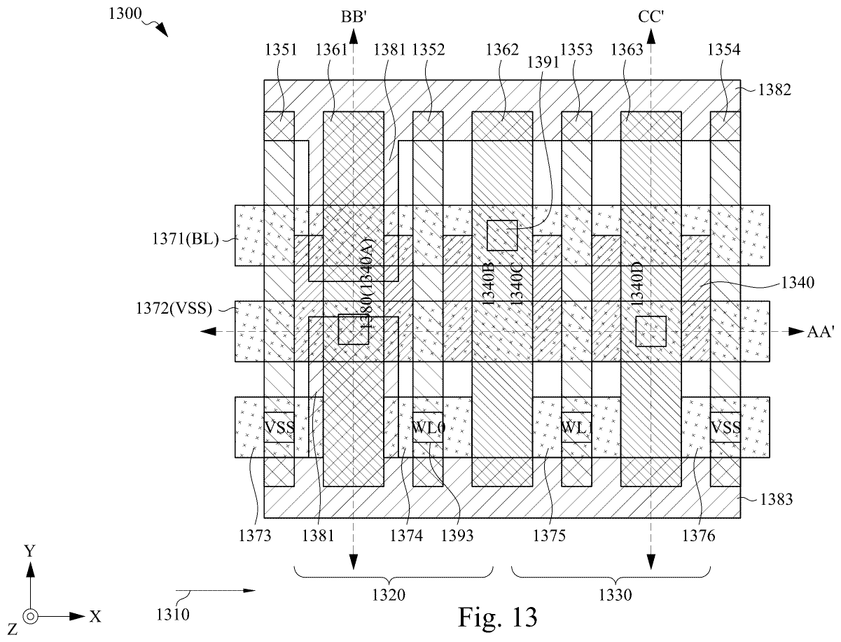

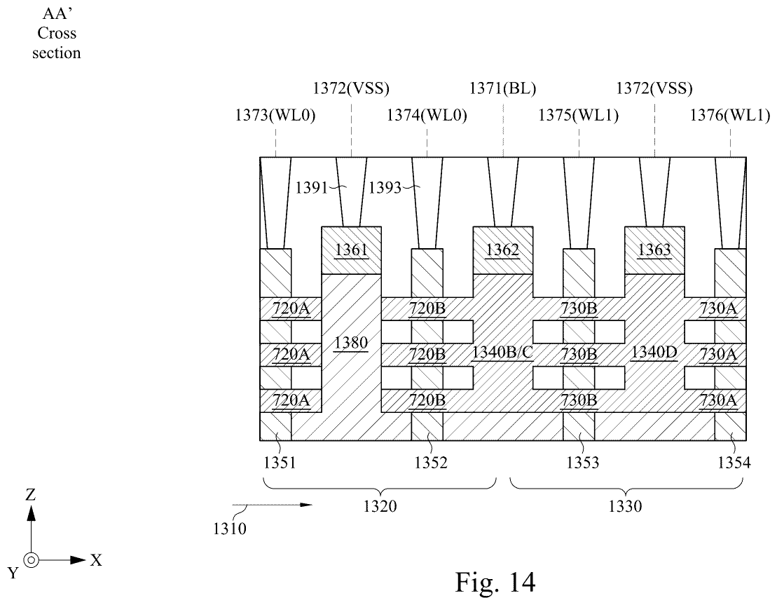

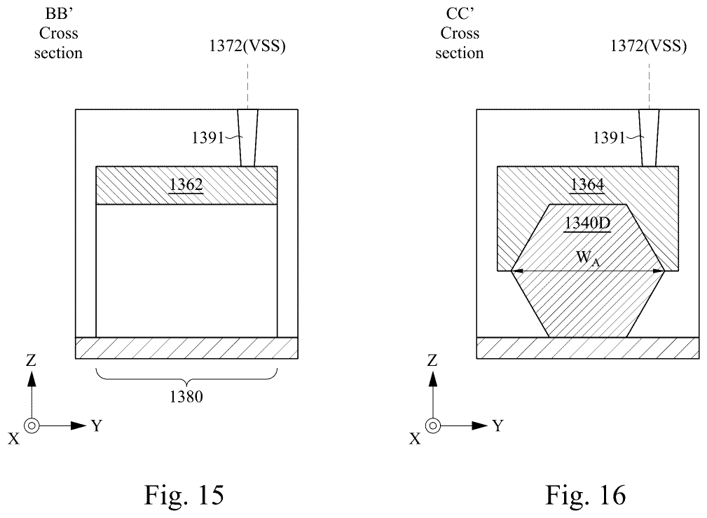

FIG. 13 illustrates an example layout 1300 configured to form (or program) a memory array 1310 including ROM cells, 1320 and 1330, that present a first logic state and a second logic state, respectively, in accordance with some embodiments. Further, FIG. 14 illustrates a hybrid cross-sectional view of the memory array 1310, FIG. 15 illustrates a cross-sectional view of the ROM cell 1320, and FIG. 16 illustrates a cross-sectional view of the ROM cell 1330. It should be understood that the layout 1300 of FIG. 13 and the corresponding cross-sectional views of FIGS. 14-16 are provided merely for illustrative purposes, and are not intended to limit the scope of the present disclosure.

Referring to FIG. 13, the layout 1300 includes patterns for forming an active region 1340, gate structures 1351, 1352, 1353, and 1354, respectively. It should be understood that the layout 1300 can include any number of other patterns to form respective active regions or gate structures, while remaining within the scope of present disclosure. In some embodiments, the active region 1340 can extend along a first lateral direction (e.g., the X-direction), and the gate structures 1351 to 1354 can each extend along a second lateral direction (e.g., the Y-direction) perpendicular to the first lateral direction. The gate structures 1351 to 1354 can each traverse the active region 1340. The gate structures 1351 to 1354 can each correspond to an active (e.g., metal) gate structure. For example, the gate structures 1351 to 1354 can define respective footprints of several later formed metal gate structures, each of which can include a gate dielectric (e.g., a high-k material) and a gate metal (e.g., one or more work function metal materials).

In some embodiments, the ROM cells of the memory array 1310 (e.g., 1320, 1330) may each be formed as a gate-all-around (GAA) transistor. However, the ROM cells of the memory array (formed by the layout 1300) can be formed as any of various other transistor structure while remaining within the scope of the present disclosure. In the example of GAA transistor structures, the active region 1340 can be formed as a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by the gate structures 1351 to 1354 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., wraps around) the remaining portions of the semiconductor structures can be configured as a gate terminal of the transistor.

In FIG. 13, the active region 1340, together with the gate structures 1351 and 1352, can form the ROM cell 1320 with a one and half-transistor (1.5T) configuration. For example, the portion of the active region 1340 overlaid by the gate structure 1351 may include a number of first nanostructures vertically separated from each other, which can collectively function as the channel of a first sub-transistor, and the portion of the active region 1340 overlaid by the gate structure 1352 may include a number of second nanostructures vertically separated from each other, which can collectively function as the channel of a second sub-transistor. In some embodiments, the gate terminal (e.g., 1351) of the first sub-transistor can be tied to VSS, causing the first sub-transistor to remain turned-off, while the gate terminal (e.g., 1352) of the second sub-transistor can be coupled to a corresponding word line. Accordingly, the first ROM cell 1320 with a 1.5T configuration can be formed.

Further, the portions of the active region 1340 that are disposed on opposite sides of each of the gate structures 1352 and 1353 are replaced with epitaxial structures, respectively. Such epitaxial structures can function as source/drain terminals of the sub-transistors. For example, the gate structure 1352 can function as a gate terminal of the active second sub-transistor, while the gate structure 1351, tied to VSS, can function as a gate terminal of the inactive (or turned-off) first sub-transistor. Epitaxial structures, 1340A and 1340B, formed on the opposite sides of the gate structure 1352 can function as a first source/drain terminal and second source/drain terminal of the second sub-transistor. Similarly, the active region 1340, together with the gate structure 1353 and gate structure 1354 which is tied to VSS, can form a second ROM cell 1330 in the same 1.5T configuration.

The layout 1300 further includes patterns for forming source/drain contact structures (sometimes referred to as MDs) 1361, 1362, and 1363, and interconnect structures 1371, 1372, 1373, 1374, 1375, and 1376, respectively. It should be understood that the layout 1300 can include any number of other patterns to form respective MDs or interconnect structures, while remaining within the scope of present disclosure. In some embodiments, the MDs 1361 to 1363 can each extend along the Y-direction, and the interconnect structures 1371 to 1376 can each extend along the X-direction. The MDs 1361 to 1363 can each be in electrical contact with a corresponding epitaxial structure (the source/drain terminal of a transistor or sub-transistor). The interconnect structures 1371 to 1376 can each be electrically coupled to one or more corresponding gate structures or one or more corresponding MDs.

In some embodiments, after forming the epitaxial structures 1340A to 1340D and prior to forming the MDs 1361 to 1363, at least a portion of the epitaxial structure 1340A can be replaced with a vertical dielectric structure 1380 (which can be better seen in the cross-sectional views of FIGS. 14-15), while other epitaxial structures 1340B-D may remain substantially intact. For example, a whole of the epitaxial structure 1340A may be replaced with the dielectric structure 1380. This can cause the channel of the active second sub-transistor of the ROM cell 1320 (e.g., the nanostructures overlaid by the gate structure 1352) to have one of its ends to directly contact the dielectric structure 1380.

Such a removal process and a replacement process can be performed based on a cut pattern 1381 included in the layout 1300. For example, the cut pattern 1381 can extend along the Y-direction and be formed wider than or equal to the corresponding MD 1361 in the X-direction. Following the cut pattern 1381, a portion of the epitaxial structure 1340A can be removed (e.g., anisotropically etched) and the removed portion can be filled with a dielectric material to form the dielectric structure 1380. As such, instead of electrically coupled to an epitaxial structure, the MD 1361 is (e.g., physically) coupled to dielectric structure 1380, causing any conductive structure formed above (and electrically connected to) the MD 1361 to be electrically isolated from an epitaxial structure. Stated another way, the MD 1361 is electrically isolated from one of the source/drain terminals of the ROM cell 1320 (or the first source/drain terminal of the second sub-transistor of the ROM cell 1320). The cut pattern 1381 can be coupled to one or more other cut patterns 1382 and 1383 that extend along the X-direction, as shown in FIG. 13. The cut patterns 1382 and 1383 can be configured to cut one or more of the gate structures 1351 to 1354 (into multiple segments), in some embodiments.

The interconnect structures 1371 to 1376 can each be formed as a metal track in one of plural metallization layers disposed over the frontside surface of the substrate, or over the MDs 1361-1363 and the gate structures 1351-1354. Each of the metallization layers can include (e.g., embed) a plural number of metal tracks in one or more dielectric layers (e.g., formed of an oxide material or a low-k dielectric material). In some embodiments, the interconnect structures 1371 to 1376 may be formed in a bottommost one of the metallization layers. Such a bottommost metallization layer is sometimes referred to as an M0 layer, and accordingly, a metal track included in the M0 layer is sometimes referred to as an M0 track. Further, in some embodiments, the M0 track 1371 can operatively serve as a bit line (BL) or a portion of the BL for the memory array 1310, the M0 tracks 1372, 1373, and 1376 can each operatively serve as a power rail carrying a ground voltage (VSS) or a portion of the power rail for the memory array 1310, the M0 track 1374 can operatively serve as a word line (WL0) or a portion of the WL0 for the memory array 1310, and the M0 track 1375 can operatively serve as another word line (WL1) or a portion of the WL1 for the memory array 1310.

The M0 track 1371 (BL) can extend along the X-direction to couple to at least the ROM cells 1320 and 1330. For example, the M0 track 1371 is coupled to the MD 1362 through at least one via structures 1391. The MD 1362 is electrically coupled to one of the source/drain terminals of the ROM cell 1320 (e.g., the epitaxial structure 1340B), and one of the source/drain terminals of the ROM cell 1330 (e.g., the epitaxial structure 1340C), in which the epitaxial structures 1340B and 1340C can be merged.

The M0 track 1372 (VSS) can also extend along the X-direction to couple to at least the ROM cells 1320 and 1330. For example, the M0 track 1372 is coupled to the MDs 1361 and 1363 through multiple via structures 1391, respectively. The MD 1361 is physically coupled to but electrically isolated from the other source/drain terminal of the ROM cell 1320 as the epitaxial structure 1340A that serves as the other source/drain terminal of the ROM cell 1320 has been replaced with the dielectric structure 1380, while the MD 1363 is electrically coupled to the other source/drain terminal of the ROM cell 1330 (e.g., the epitaxial structure 1340D).

The M0 track 1374 (WL0) can also extend along the X-direction to couple to the ROM cell 1320. For example, the M0 track 1374 is coupled to the gate structure 1352 through at least one via structures 1393. The gate structure 1352 can serve as the active gate terminal of the ROM cell 1320, while the gate structure 1351 can serve as the inactive gate terminal of the ROM cell 1320. Similarly, the M0 track 1375 (WL1) can also extend along the X-direction to couple to the ROM cell 1330. For example, the M0 track 1375 is coupled to the gate structure 1353 through at least one via structures 1393. The gate structure 1353 can serve as the active gate terminal of the ROM cell 1330, while the gate structure 1354 can serve as the inactive gate terminal of the ROM cell 1330.

Referring next to FIG. 14, the hybrid cross-sectional view includes a plural number of cross-sectional views of the memory array 1310, each of which is cut along line AA′ (indicated in FIG. 13). As shown in FIG. 14, the epitaxial structure 1340A is replaced by the dielectric structure 1380, which causes one of the source/drain terminals of the ROM cell 1320 to be electrically isolated from the interconnect structure 1372 (VSS). The channel of the active second sub-transistor (e.g., nanostructures 720B overlaid or wrapped by the gate structure 1352) has one end in direct contact with the dielectric structure 1380, with the other end electrically coupled to the epitaxial structures 1340B-C. Equivalently, the ROM cell 1320 has one of its source/drain terminals disconnected from the interconnect structure 1372 (VSS) and the other source/drain terminal coupled to the interconnect structure 1371 (BL). As a result, the ROM cell 1320 may conduct a first current, a level of which is relatively low or close to zero. It should be noted that the channel of the inactive first sub-transistor (e.g., nanostructures 720A overlaid or wrapped by the gate structure 1351) may be turned off, given that the gate structure 1351 is tied to VSS.

FIG. 15 further illustrates another cross-sectional view of the memory array 1310 cut along line BB′ (indicated in FIG. 13). For example, the cross-sectional view of FIG. 15 is cut along the dielectric structure 1380. As shown, the dielectric structure 1380 may have a whole of its top surface in contact with a bottom surface of the MD 1361, while a top surface of the MD 1361 is electrically connected to the interconnect structure 1372 (VSS) through one of the via structures 1391. In some embodiments, the dielectric structure 1380 may have its sidewalls each in contact with no epitaxial structure. Such sidewalls of the dielectric structure 1380 can face the Y-direction. Stated another way, the MD 1361 has no portion in contact with an epitaxial structure.

Referring again to FIG. 14, the epitaxial structures 1340D retains, which causes one of the source/drain terminals of the ROM cell 1330 to be electrically couped to the interconnect structure 1372 (VSS). The channel of the active second sub-transistor (e.g., nanostructures 730B overlaid or wrapped by the gate structure 1375) has one end electrically coupled to the epitaxial structures 1340B-C, with the other end electrically coupled to the epitaxial structure 1340D. Equivalently, the ROM cell 1330 has one of its source/drain terminals coupled to the interconnect structure 1372 (VSS) and the other source/drain terminal coupled to the interconnect structure 1371 (BL). As a result, the ROM cell 1330 may conduct a second current, a level of which is relatively high. It should be noted that the channel of the inactive first sub-transistor (e.g., nanostructures 730A overlaid or wrapped by the gate structure 1354) may be turned off, given that the gate structure 1354 is tied to VSS.

FIG. 16 further another cross-sectional view of the memory array 1310 cut along line CC′ (indicated in FIG. 13). For example, the cross-sectional view of FIG. 16 is cut along the epitaxial structure 1340D. As shown, the epitaxial structure 1340D may have a whole of its top surface in contact with a bottom surface of the MD 1363, and a top surface of the MD 1363 is electrically connected to the interconnect structure 1372 (VSS) through one of the via structures 1391. In some embodiments, a whole of the epitaxial structure 1340D is electrically coupled to the MID 1363. Stated another way, the MD 1363 has a portion with a width along the Y-direction (WA) in contact with the epitaxial structure 1340D, or the epitaxial structure 1340D has a width along the Y-direction (WA) in contact with the MD 1363.

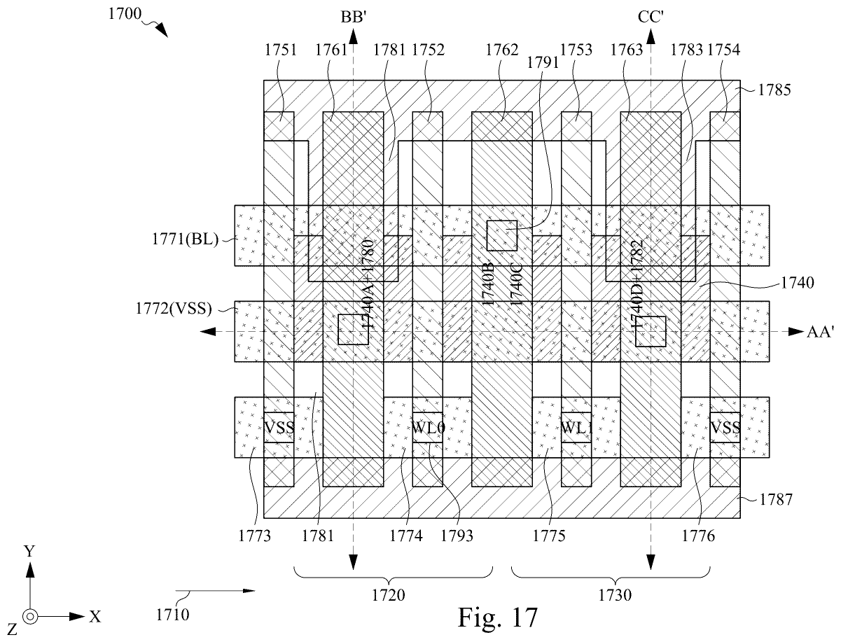

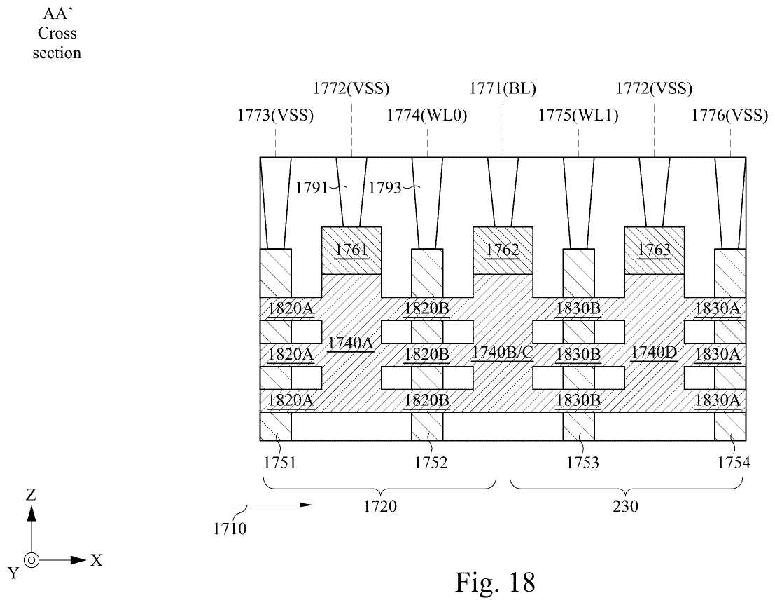

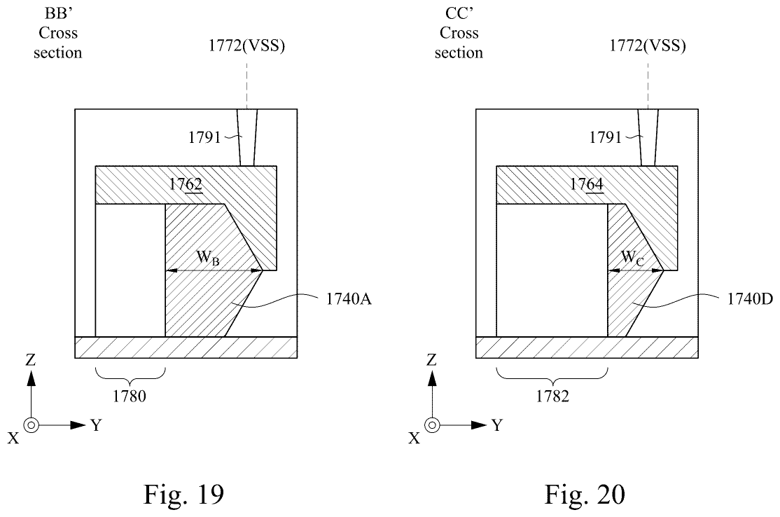

FIG. 17 illustrates an example layout 1700 configured to form (or program) a memory array 1710 including ROM cells, 1720 and 1730, that present a first logic state and a second logic state, respectively, in accordance with some embodiments. Further, FIG. 18 illustrates a hybrid cross-sectional view of the memory array 1710, FIG. 19 illustrates a cross-sectional view of the ROM cell 1720, and FIG. 20 illustrates a cross-sectional view of the ROM cell 1730. It should be understood that the layout 1700 of FIG. 17 and the corresponding cross-sectional views of FIGS. 18-20 are provided merely for illustrative purposes, and are not intended to limit the scope of the present disclosure.

Referring to FIG. 17, the layout 1700 includes patterns for forming an active region 1740, gate structures 1751, 1752, 1753, and 1754, respectively. It should be understood that the layout 1700 can include any number of other patterns to form respective active regions or gate structures, while remaining within the scope of present disclosure. In some embodiments, the active region 1740 can extend along a first lateral direction (e.g., the X-direction), and the gate structures 1751 to 1754 can each extend along a second lateral direction (e.g., the Y-direction) perpendicular to the first lateral direction. The gate structures 1751 to 1754 can each traverse the active region 1740. The gate structures 1751 to 1754 can each correspond to an active (e.g., metal) gate structure. For example, the gate structures 1751 to 1754 can define respective footprints of several later formed metal gate structures, each of which can include a gate dielectric (e.g., a high-k material) and a gate metal (e.g., one or more work function metal materials).

In some embodiments, the ROM cells of the memory array 1710 (e.g., 1720, 1730) may each be formed as a gate-all-around (GAA) transistor. However, the ROM cells of the memory array (formed by the layout 1700) can be formed as any of various other transistor structure while remaining within the scope of the present disclosure. In the example of GAA transistor structures, the active region 1740 can be formed as a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by the gate structures 1751 to 1754 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., wraps around) the remaining portions of the semiconductor structures can be configured as a gate terminal of the transistor.

In FIG. 17, the active region 1740, together with the gate structures 1751 and 1752, can form the ROM cell 1720 with the above-described 1.5T configuration. For example, the portion of the active region 1740 overlaid by the gate structure 1751 may include a number of first nanostructures vertically separated from each other, which can collectively function as the channel of a first sub-transistor, and the portion of the active region 1740 overlaid by the gate structure 1752 may include a number of second nanostructures vertically separated from each other, which can collectively function as the channel of a second sub-transistor. In some embodiments, the gate terminal (e.g., 1751 ) of the first sub-transistor can be tied to VSS, causing the first sub-transistor to remain turned-off, while the gate terminal (e.g., 1752) of the second sub-transistor can be coupled to a corresponding word line. Accordingly, the first ROM cell 1720 with a 1.5T configuration can be formed.

Further, the portions of the active region 1740 that are disposed on opposite sides of each of the gate structures 1752 and 1753 are replaced with epitaxial structures, respectively. Such epitaxial structures can function as source/drain terminals of the sub-transistors. For example, the gate structure 1752 can function as a gate terminal of the active second sub-transistor, while the gate structure 1751, tied to VSS, can function as a gate terminal of the inactive (or turned-off) first sub-transistor. Epitaxial structures, 1740A and 1740B, formed on the opposite sides of the gate structure 1752 can function as a first source/drain terminal and second source/drain terminal of the second sub-transistor. Similarly, the active region 1740, together with the gate structure 1753 and gate structure 1754 which is tied to VSS, can form a second ROM cell 1730 in the same 1.5T configuration.

The layout 1700 further includes patterns for forming source/drain contact structures (sometimes referred to as MDs) 1761, 1762, and 1763, and interconnect structures 1771, 1772, 1773, 1774, 1775, and 1776, respectively. It should be understood that the layout 1700 can include any number of other patterns to form respective MDs or interconnect structures, while remaining within the scope of present disclosure. In some embodiments, the MDs 1761 to 1763 can each extend along the Y-direction, and the interconnect structures 1771 to 1776 can each extend along the X-direction. The MDs 1761 to 1763 can each be in electrical contact with a corresponding epitaxial structure (the source/drain terminal of a transistor or sub-transistor). The interconnect structures 1771 to 1776 can each be electrically coupled to one or more corresponding gate structures or one or more corresponding MDs.

In some embodiments, after forming the epitaxial structures 1740A to 1740D and prior to forming the MDs 1761 to 1763, at least a portion of the epitaxial structure 1740A can be replaced with a vertical dielectric structure 1780 (which can be better seen in the cross-sectional views of FIGS. 18 and 19) and at least a portion of the epitaxial structure 1740D can be replaced with a vertical dielectric structure 1782 (which can be better seen in the cross-sectional views of FIGS. 18 and 20), while other epitaxial structures 1740B-C may remain substantially intact.

For example, ½ of the epitaxial structure 1740A may be replaced with the dielectric structure 1780. This can cause the channel of the second sub-transistor of the ROM cell 1720 (e.g., the nanostructures overlaid by the gate structure 1752) to have one of its ends to directly contact a combination of the dielectric structure 1780 and the remaining portion of the epitaxial structure 1740A (e.g., ⅔ of the epitaxial structure 1740A). In another example, ⅔ of the epitaxial structure 1740D may be replaced with the dielectric structure 1782. This can cause the channel of the second sub-transistor of the ROM cell 1730 (e.g., the nanostructures overlaid by the gate structure 1753) to have one of its ends to directly contact a combination of the dielectric structure 1782 and the remaining portion of the epitaxial structure 1740D (e.g., ⅓ of the epitaxial structure 1740D).

Such a removal process and a replacement process can be performed based on cut patterns 1781 and 1783 included in the layout 1700. For example, the cut pattern 1781 can extend along the Y-direction and be formed wider than or equal to the corresponding MD 1761 in the X-direction. Further, the cut pattern 1781 can overlay ⅓ of the epitaxial structure 1740A. For another example, the cut pattern 1783 can extend along the Y-direction and be formed wider than or equal to the corresponding MD 1763 in the X-direction. Further, the cut pattern 1783 can overlay ⅔ of the epitaxial structure 1740D. Following the cut pattern 1781, ⅓ of the epitaxial structure 1740A can be removed (e.g., anisotropically etched) and the removed portion can be filled with a dielectric material to form the dielectric structure 1780. Similarly, following the cut pattern 1783, ⅔ of the epitaxial structure 1740D can be removed (e.g., anisotropically etched) and the removed portion can be filled with a dielectric material to form the dielectric structure 1782.

As such, the MD 1761 is (e.g., physically) coupled to the dielectric structure 1780 and the ⅔ of the epitaxial structure 1740A combined, causing any conductive structure formed above (and electrically connected to) the MD 1761 to be electrically coupled to the ⅔ of the epitaxial structure 1740A. Stated another way, the MD 1761 is electrically connected to one of the source/drain terminals of the ROM cell 1720 (or the first source/drain terminal of the second sub-transistor of the ROM cell 1720). Similarly, the MD 1763 is (e.g., physically) coupled to the dielectric structure 1782 and the ⅓ of the epitaxial structure 1740D combined, causing any conductive structure formed above (and electrically connected to) the MD 1764 to be electrically coupled to the ½ of the epitaxial structure 1740D. Stated another way, the MD 1764 is electrically connected to one of the source/drain terminals of the ROM cell 1730 (or the first source/drain terminal of the second sub-transistor of the ROM cell 1730). The cut patterns 1781 and 1783 can each be coupled to one of other cut pattern 1785 or 1787 that extends along the X-direction, as shown in FIG. 17. For example, both of the cut patterns 1781 and 1783 have one of their ends connected to the cut pattern 1785. The cut patterns 1785 and 1787 can be configured to cut one or more of the gate structures 1751 to 1754 (into multiple segments), in some embodiments.

The interconnect structures 1771 to 1776 can each be formed as a metal track in one of plural metallization layers disposed over the frontside surface of the substrate, or over the MDs 1761-1763 and the gate structures 1751-1754. Each of the metallization layers can include (e.g., embed) a plural number of metal tracks in one or more dielectric layers (e.g., formed of an oxide material or a low-k dielectric material). In some embodiments, the interconnect structures 1771 to 1776 may be formed in a bottommost one of the metallization layers. Such a bottommost metallization layer is sometimes referred to as an M0 layer, and accordingly, a metal track included in the M0 layer is sometimes referred to as an M0 track. Further, in some embodiments, the M0 track 1771 can operatively serve as a bit line (BL) or a portion of the BL for the memory array 1710, the M0 tracks 1772, 1773, and 1776 can each operatively serve as a power rail carrying a ground voltage (VSS) or a portion of the power rail for the memory array 1710, the M0 track 1774 can operatively serve as a word line (WL0) or a portion of the WL0 for the memory array 1710, and the M0 track 1775 can operatively serve as another word line (WL1) or a portion of the WL1 for the memory array 1710.

The M0 track 1771 (BL) can extend along the X-direction to couple to at least the ROM cells 1720 and 1730. For example, the M0 track 1771 is coupled to the MD 1762 through via structure 1791. The MD 1762 is electrically coupled to one of the source/drain terminals of the ROM cell 1720 (e.g., the epitaxial structure 1740B), and one of the source/drain terminals of the ROM cell 1730 (e.g., the epitaxial structure 1740C), in which the epitaxial structures 1740B and 1740C are merged. The M0 track 1772 (VSS) can also extend along the X-direction to couple to at least the ROM cells 1720 and 1730. For example, the M0 track 1772 is coupled to the MDs 1761 and 1763 through multiple via structures 1791, respectively. The MD 1761 is physically and electrically coupled to the other source/drain terminal of the ROM cell 1720 (e.g., the remaining ⅔ of the epitaxial structure 1740A), and the MD 1763 is physically and electrically coupled to the other source/drain terminal of the ROM cell 1730 (e.g., the remaining ⅓ of the epitaxial structure 1740D).

The M0 track 1774 (WL0) can also extend along the X-direction to couple to the ROM cell 1720. For example, the M0 track 1774 is coupled to the gate structure 1752 through via structure 1793. The gate structure 1752 can serve as the gate terminal of the ROM cell 1720, while the gate structure 1751 may operate as an inactive gate terminal of the ROM cell 1720 by coupling to VSS through the M0 track 1773. Similarly, the M0 track 1775 (WL1) can also extend along the X-direction to couple to the ROM cell 1730. For example, the M0 track 1775 is coupled to the gate structure 1753 through via structure 1793. The gate structure 1753 can serve as the gate terminal of the ROM cell 1730, while the gate structure 1754 may operate as an inactive gate terminal of the ROM cell 1730 by coupling to VSS through the M0 track 1776.

Referring next to FIG. 18, the hybrid cross-sectional view includes a plural number of cross-sectional views of the memory array 1710, each of which is cut along line AA′ (indicated in FIG. 17). As shown in FIG. 18, the epitaxial structure 1740A still have a portion retained and in contact with the dielectric structure 1780 (FIG. 19), which causes one of the source/drain terminals of the second sub-transistor of the ROM cell 1720 to remain electrically coupled to the interconnect structure 1772 (VSS). The channel of the second sub-transistor (e.g., nanostructures 1820B overlaid or wrapped by the gate structure 1752) has one end electrically coupled to the remaining portion of the epitaxial structure 1740A and the dielectric structure 1780, with the other end electrically coupled to the epitaxial structures 1740B-C. Equivalently, the ROM cell 1720 has one of its source/drain terminals, with a reduced portion (e.g., ⅔ of the original size), coupled to the interconnect structure 1772 (VSS) and the other source/drain terminal coupled to the interconnect structure 1771 (BL). As a result, the ROM cell 1720 may conduct a third current, a level of which is higher than the first current (flowing through the ROM cell 1320 of FIGS. 13-16) and lower than the second current (flowing through the ROM cell 1330 of FIGS. 13-16).

FIG. 19 further illustrates another cross-sectional view of the memory array 1710 cut along line BB′ (indicated in FIG. 17). For example, the cross-sectional view of FIG. 19 is cut along the dielectric structure 1780 and the epitaxial structure 1740A. As shown, the epitaxial structure 1740A may have a sidewall (facing the Y-direction) in contact with the dielectric structure 1780. Respective top surfaces of the dielectric structure 1780 and the epitaxial structure 1740A may be in contact with a bottom surface of the MD 1761, while a top surface of the MD 1761 is electrically connected to the interconnect structure 1772 (VSS) through one of the via structures 1791. In some embodiments, the MD 1761 has a portion with a width along the Y-direction (W_{B}) in contact with the (remaining) epitaxial structure 1740A, or the (remaining) epitaxial structure 1740A has a width along the Y-direction (WB) in contact with the MD 1761.

Referring again to FIG. 18, the epitaxial structure 1740D still has a portion retained and in contact with the dielectric structure 1782 (FIG. 20), which causes one of the source/drain terminals of the second sub-transistor of the ROM cell 1730 to remain electrically coupled to the interconnect structure 1772 (VSS). The channel of the second sub-transistor (e.g., nanostructures 1830B overlaid or wrapped by the gate structure 1753) has one end electrically coupled to the remaining portion of the epitaxial structure 1740D and the dielectric structure 1782, with the other end electrically coupled to the epitaxial structures 1740B-C. Equivalently, the ROM cell 1730 has one of its source/drain terminals, with a reduced portion (e.g., ⅓ of the original size), coupled to the interconnect structure 1772 (VSS) and the other source/drain terminal coupled to the interconnect structure 1771 (BL). As a result, the ROM cell 1730 may conduct a fourth current, a level of which is higher than the first current (flowing through the ROM cell 1320 of FIGS. 13-16) and lower than the third current (flowing through the ROM cell 1720 of FIGS. 17-20).

FIG. 20 further illustrates another cross-sectional view of the memory array 1710 cut along line CC′ (indicated in FIG. 17). For example, the cross-sectional view of FIG. 20 is cut along the dielectric structure 1782 and the epitaxial structure 1740D. As shown, the epitaxial structure 1740D may have a sidewall (facing the Y-direction) in contact with the dielectric structure 1782. Respective top surfaces of the dielectric structure 1782 and the epitaxial structure 1740D may be in contact with a bottom surface of the MD 1763, while a top surface of the MD 1763 is electrically connected to the interconnect structure 1772 (VSS) through one of the via structures 1791. In some embodiments, the MD 1763 has a portion with a width along the Y-direction (W_{C}) in contact with the (remaining) epitaxial structure 1740D, or the (remaining) epitaxial structure 1740D has a width along the Y-direction (W_{C}) in contact with the MD 1763.

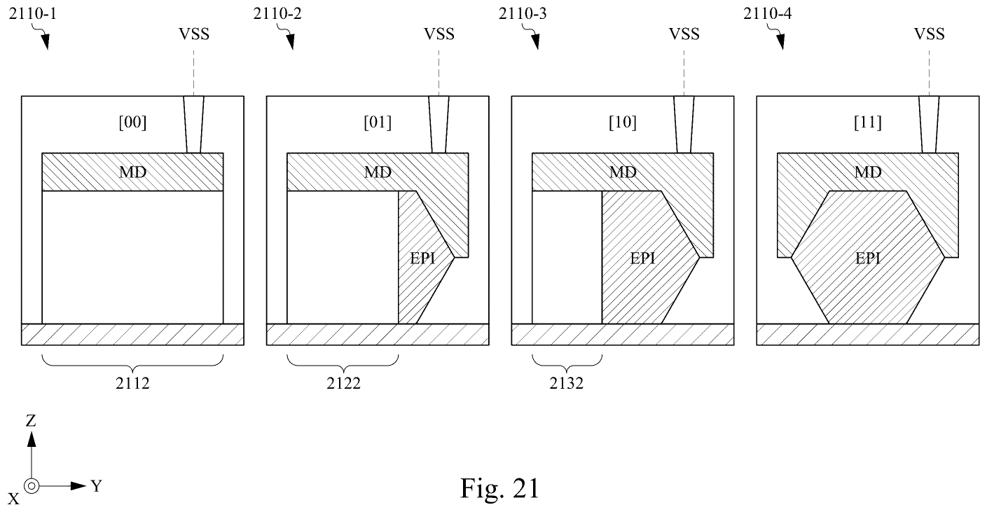

FIG. 21 illustrates four different logic states, [00], [01], [10], and [11], presented by ROM cells, 2110-1, 2110-2, 2110-3, and 2110-4, respectively, in accordance with some embodiments. As shown, the ROM cells 2110-1 to 2110-4 each have at least one of its epitaxial structures with a respective width in the Y-direction to contact an MD, which is further coupled to an interconnect structure configured as a power rail carrying a ground voltage (e.g., VSS). In some embodiments, by connecting different sizes of the epitaxial structures to VSS, the ROM cells 2110-1 to 2110-4 may be referred to as being programed through or coded on VSS.

For example, the ROM cell 2110-1 has one source/drain terminal replaced by a vertical dielectric structure 2112 and the other source/drain terminal retained, similar to the ROM cell 1320 (FIG. 13); the ROM cell 2110-2 has one source/drain terminal with ⅔ replaced by a vertical dielectric structure 2122 and the other source/drain terminal retained, similar to the ROM cell 1730 (FIG. 17); the ROM cell 2110-3 has one source/drain terminal with ⅓ replaced by a vertical dielectric structure 2132 and the other source/drain terminal retained, similar to the ROM cell 1720 (FIG. 17); and the ROM cell 2110-4 has both of its source/drain terminals retained, similar to the ROM cell 1330 (FIG. 13). As such, the ROM cells 2110-1, 2110-2, 2110-3, and 2110-4 can conduct four differentiable currents. For example, the ROM cell 2110-4 can conduct the highest current, the ROM cell 2110-3 can conduct the next highest current, the ROM cell 2110-2 can conduct the next lowest current, and the ROM cell 2110-1 can conduct the lowest current, causing the ROM cells 2110-4, 2110-3, 2110-2, and 2110-1 to present four different logic states, [11], [10], [01], and [00], respectively.

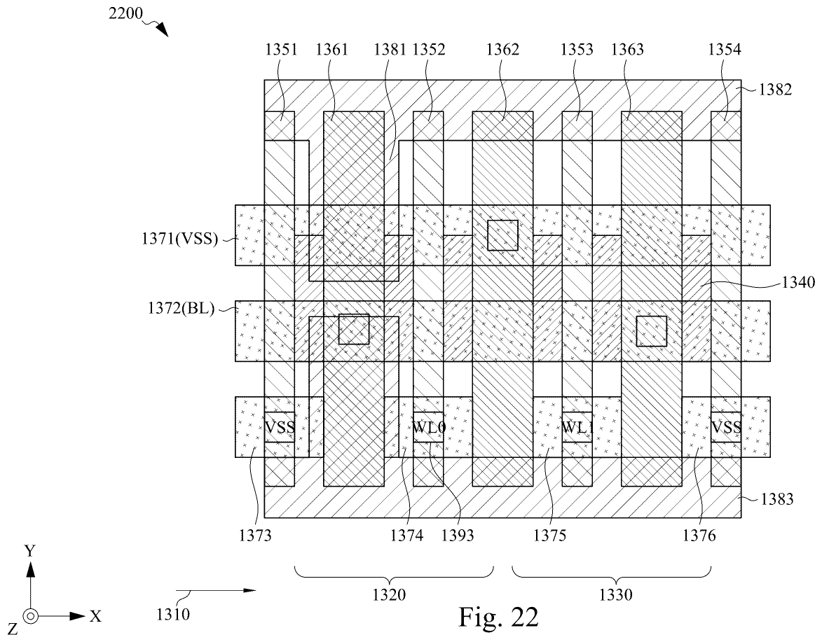

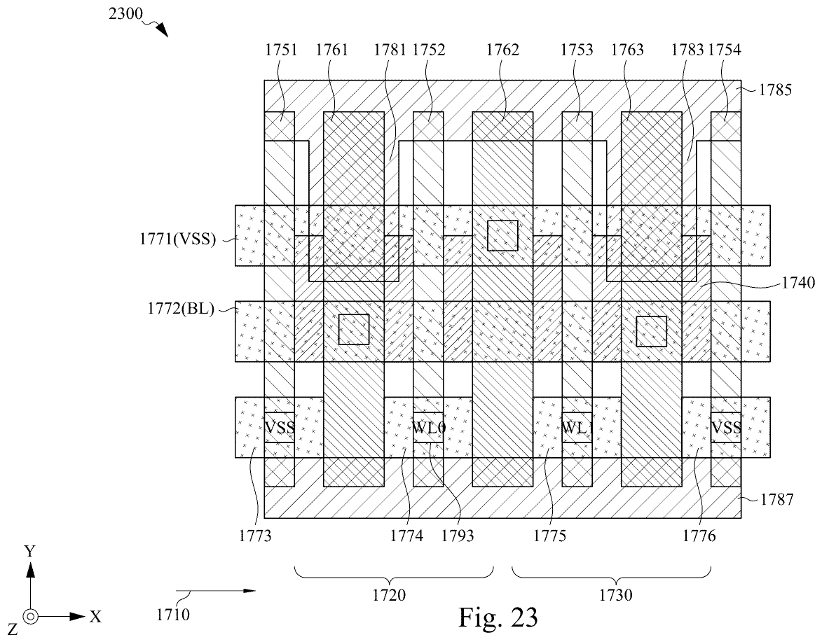

FIG. 22 and FIG. 23 illustrate example layouts 2200 and 2300, respectively, each of which is configured to form (or program) a memory array including two ROM cells that respectively present different logic states, in accordance with some embodiments. The layouts 2200 and 2300 are substantially similar to the layout 1300 (FIG. 13) and layout 1700 (FIG. 17), respectively, except that the functionalities of the interconnect structures 1371 and 1372 are switched in the layout 2200 and the functionalities of the interconnect structures 1771 and 1772 are switched in the layout 2300. Accordingly, the reference numerals of FIG. 13 and FIG. 17 are reused in the following discussion of FIG. 22 and FIG. 23, respectively.

Referring first to FIG. 22, similar to the layout 1300, the layout 2200 includes the patterns for forming the active region 1340, the gate structures 1351 to 1354, the MDs 1361 to 1363, and the M0 tracks 1371 to 1376, and the cut patterns 1381 to 1383. However, according to the layout 2200, the M0 tracks 1371 and 1372 are configured as the power rail carrying VSS and the BL, respectively. As such, the ROM cell 1320 may have one of its source/drain terminals replaced by a dielectric structure which is electrically isolated from the BL, and the ROM cell 1330 may have its source/drain terminals electrically coupled to the BL and VSS, respectively. The ROM cells 1320 and 1330, formed based on the layout 2200, may thus be referred to as being programed through or coded on BL.

Referring next to FIG. 23, the layout 2300, similar to the layout 1700, includes the patterns for forming the active region 1740, the gate structures 1751 to 1754, the MDs 1761 to 1763, and the M0 tracks 1771 to 1776, and the cut patterns 1781 to 1787. However, according to the layout 2300, the M0 tracks 1771 and 1772 are configured as the power rail carrying VSS and the BL, respectively. As such, the ROM cell 1720 may have one of its source/drain terminals partially replaced by a dielectric structure and electrically coupled to the BL, and the ROM cell 1730 may have its source/drain terminals partially replaced by another dielectric structure and electrically coupled to the BL. The ROM cells 1720 and 1730, formed based on the layout 2300, may thus be referred to as being programed through or coded on BL.

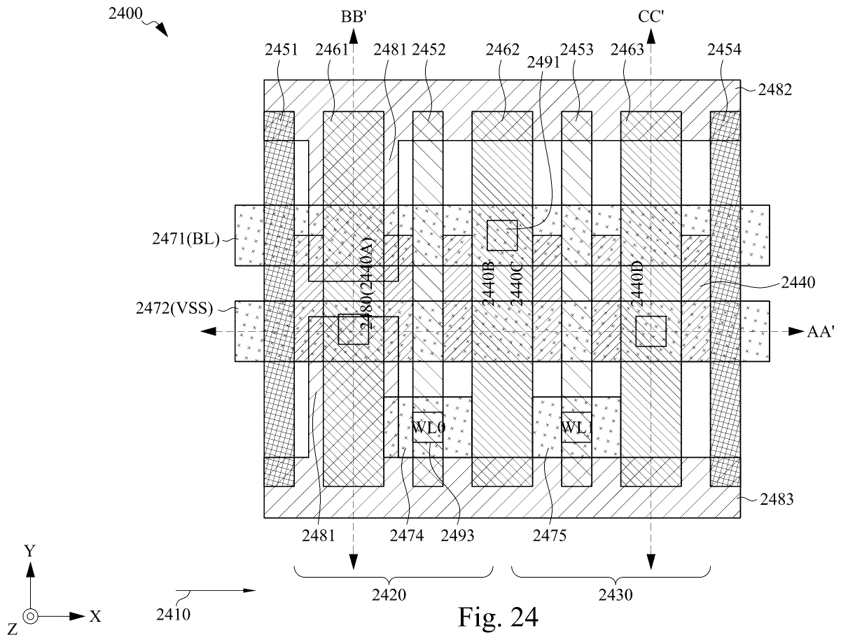

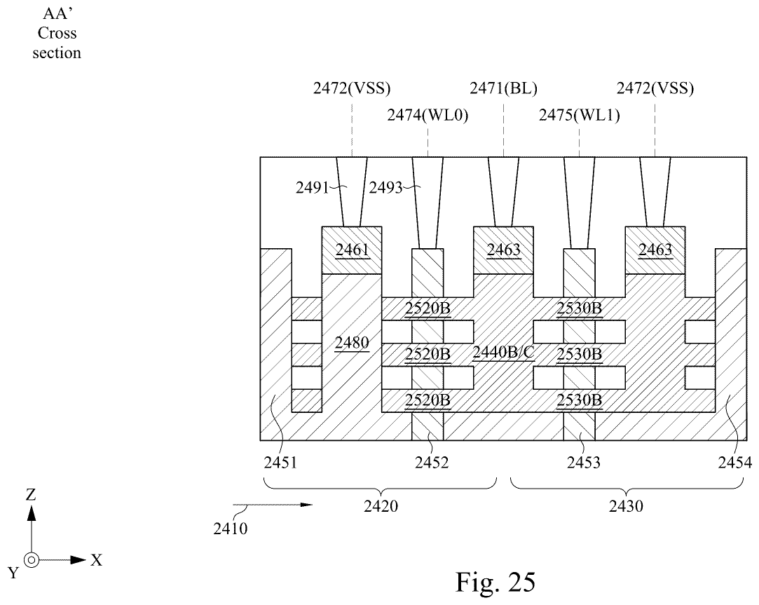

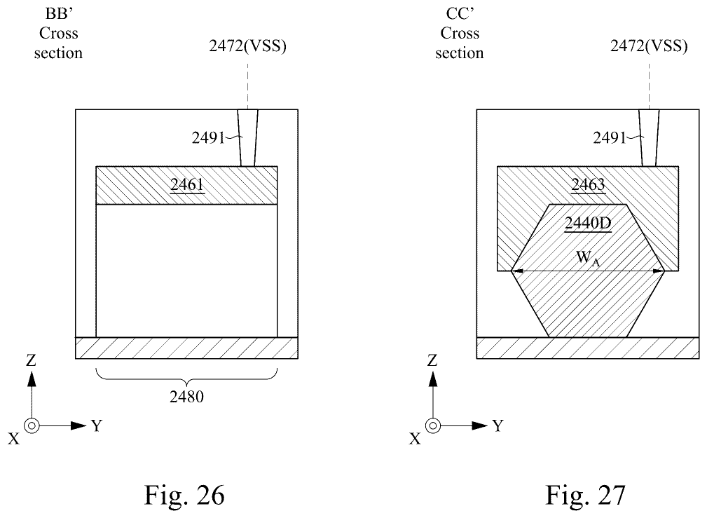

FIG. 24 illustrates an example layout 2400 configured to form (or program) a memory array 2410 including ROM cells, 2420 and 2430, that present a first logic state and a second logic state, respectively, in accordance with some embodiments. Further, FIG. 25 illustrates a hybrid cross-sectional view of the memory array 2410, FIG. 26 illustrates a cross-sectional view of the ROM cell 2420, and FIG. 27 illustrates a cross-sectional view of the ROM cell 2430. It should be understood that the layout 2400 of FIG. 24 and the corresponding cross-sectional views of FIGS. 25-27 are provided merely for illustrative purposes, and are not intended to limit the scope of the present disclosure.

Referring to FIG. 24, the layout 2400 includes patterns for forming an active region 2440, gate structures 2451, 2452, 2453, and 2454, respectively. It should be understood that the layout 2400 can include any number of other patterns to form respective active regions or gate structures, while remaining within the scope of present disclosure. In some embodiments, the active region 2440 can extend along a first lateral direction (e.g., the X-direction), and the gate structures 2451 to 2454 can each extend along a second lateral direction (e.g., the Y-direction) perpendicular to the first lateral direction. The gate structures 2451 to 2454 can each traverse the active region 2440. In some embodiments, the gate structures 2452 and 2453 can each correspond to an active (e.g., metal) gate structure, while the gate structures 2451 and 2454 can each correspond to an inactive (e.g., dielectric) gate structures. For example, the gate structures 2451 to 2454 can define respective footprints of several later formed gate structures, in which the gate structures 2452 and 2453 may each be formed as a metal gate structure and the gate structures 2451 and 2454 may each be formed as a dielectric gate structure. In some embodiments, the metal gate structure can include a gate dielectric (e.g., a high-k material) and a gate metal (e.g., one or more work function metal materials), while the dielectric gate structure may be formed of a dielectric material. In some embodiments, the dielectric gate structure (e.g., 2451, 2454) may first be formed as a poly-silicon gate structure and then be replaced with a dielectric material.

In some embodiments, the ROM cells of the memory array 2410 (e.g., 2420, 2430) may each be formed as a gate-all-around (GAA) transistor. However, the ROM cells of the memory array (formed by the layout 2400) can be formed as any of various other transistor structure while remaining within the scope of the present disclosure. In the example of GAA transistor structures, the active region 2440 can be formed as a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by the gate structures 2451 to 2454 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., wraps around) the remaining portions of the semiconductor structures can be configured as a gate terminal of the transistor.

In FIG. 24, the active region 2440, together with the gate structures 2451 and 2452, can form the ROM cell 2420 with a one and half-transistor (1.5T) configuration. For example, the portion of the active region 2440 overlaid by the gate structure 2451 may include a number of first nanostructures vertically separated from each other, which can collectively function as the channel of a first sub-transistor, and the portion of the active region 2440 overlaid by the gate structure 2452 may include a number of second nanostructures vertically separated from each other, which can collectively function as the channel of a second sub-transistor. In some embodiments, the gate terminal (e.g., 2451) of the first sub-transistor can later be replaced with a dielectric material, causing the first sub-transistor to remain turned-off, while the gate terminal (e.g., 2452) of the second sub-transistor can be coupled to a corresponding word line. Accordingly, the first ROM cell 2420 with a 1.5T configuration can be formed.

Further, the portions of the active region 2440 that are disposed on opposite sides of each of the gate structures 2452 and 2453 are replaced with epitaxial structures, respectively. Such epitaxial structures can function as source/drain terminals of the sub-transistors. For example, the gate structure 2452 can function as a gate terminal of the active second sub-transistor, while the gate structure 2451, replaced with a dielectric material, can function as a gate terminal of the inactive (or turned-off) first sub-transistor. Epitaxial structures, 2440A and 2440B, formed on the opposite sides of the gate structure 2452 can function as a first source/drain terminal and second source/drain terminal of the second sub-transistor. Similarly, the active region 2440, together with the gate structure 2453 and gate structure 2454 which is replaced with a dielectric material, can form a second ROM cell 2430 in the same 1.5T configuration.

The layout 2400 further includes patterns for forming source/drain contact structures (sometimes referred to as MDs) 2461, 2462, and 2463, and interconnect structures 2471, 2472, 2473, and 2474, respectively. It should be understood that the layout 2400 can include any number of other patterns to form respective MDs or interconnect structures, while remaining within the scope of present disclosure. In some embodiments, the MDs 2461 to 2463 can each extend along the Y-direction, and the interconnect structures 2471 to 2474 can each extend along the X-direction. The MDs 2461 to 2463 can each be in electrical contact with a corresponding epitaxial structure (the source/drain terminal of a transistor or sub-transistor). The interconnect structures 2471 to 2474 can each be electrically coupled to one or more corresponding gate structures or one or more corresponding MDs.

In some embodiments, after forming the epitaxial structures 2440A to 2440D and prior to forming the MDs 2461 to 2463, at least a portion of the epitaxial structure 2440A can be replaced with a vertical dielectric structure 2480 (which can be better seen in the cross-sectional views of FIGS. 25-26), while other epitaxial structures 2440B-D may remain substantially intact. For example, a whole of the epitaxial structure 2440A may be replaced with the dielectric structure 2480. This can cause the channel of the active second sub-transistor of the ROM cell 2420 (e.g., the nanostructures overlaid by the gate structure 2452) to have one of its ends to directly contact the dielectric structure 2480.

Such a removal process and a replacement process can be performed based on a cut pattern 2481 included in the layout 2400. For example, the cut pattern 2481 can extend along the Y-direction and be formed wider than or equal to the corresponding MD 2461 in the X-direction. Following the cut pattern 2481, a portion of the epitaxial structure 2440A can be removed (e.g., anisotropically etched) and the removed portion can be filled with a dielectric material to form the dielectric structure 2480. As such, instead of electrically coupled to an epitaxial structure, the MD 2461 is (e.g., physically) coupled to dielectric structure 2480, causing any conductive structure formed above (and electrically connected to) the MD 2461 to be electrically isolated from an epitaxial structure. Stated another way, the MD 2461 is electrically isolated from one of the source/drain terminals of the ROM cell 2420 (or the first source/drain terminal of the second sub-transistor of the ROM cell 2420). The cut pattern 2481 can be coupled to one or more other cut patterns 2482 and 2483 that extend along the X-direction, as shown in FIG. 24. The cut patterns 2482 and 2483 can be configured to cut one or more of the gate structures 2451 to 2454 (into multiple segments), in some embodiments.

The interconnect structures 2471 to 2474 can each be formed as a metal track in one of plural metallization layers disposed over the frontside surface of the substrate, or over the MDs 2461-2463 and the gate structures 2451-2454. Each of the metallization layers can include (e.g., embed) a plural number of metal tracks in one or more dielectric layers (e.g., formed of an oxide material or a low-k dielectric material). In some embodiments, the interconnect structures 2471 to 2474 may be formed in a bottommost one of the metallization layers. Such a bottommost metallization layer is sometimes referred to as an M0 layer, and accordingly, a metal track included in the M0 layer is sometimes referred to as an M0 track. Further, in some embodiments, the M0 track 2471 can operatively serve as a bit line (BL) or a portion of the BL for the memory array 2410, the M0 tracks 2472 can operatively serve as a power rail carrying a ground voltage (VSS) or a portion of the power rail for the memory array 2410, the M0 track 2473 can operatively serve as a word line (WL0) or a portion of the WL0 for the memory array 2410, and the M0 track 2474 can operatively serve as another word line (WL1) or a portion of the WL1 for the memory array 2410.

The M0 track 2471 (BL) can extend along the X-direction to couple to at least the ROM cells 2420 and 2430. For example, the M0 track 2471 is coupled to the MD 2462 through at least one via structures 2491. The MD 2462 is electrically coupled to one of the source/drain terminals of the ROM cell 2420 (e.g., the epitaxial structure 2440B), and one of the source/drain terminals of the ROM cell 2430 (e.g., the epitaxial structure 2440C), in which the epitaxial structures 2440B and 2440C can be merged.

The M0 track 2472 (VSS) can also extend along the X-direction to couple to at least the ROM cells 2420 and 2430. For example, the M0 track 2472 is coupled to the MDs 2461 and 2463 through multiple via structures 2491, respectively. The MD 2461 is physically coupled to but electrically isolated from the other source/drain terminal of the ROM cell 2420 as the epitaxial structure 2440A that serves as the other source/drain terminal of the ROM cell 2420 has been replaced with the dielectric structure 2480, and the MD 2463 is electrically coupled to the other source/drain terminal of the ROM cell 2430 (e.g., the epitaxial structure 2440D).

The M0 track 2473 (WL0) can also extend along the X-direction to couple to the ROM cell 2420. For example, the M0 track 2473 is coupled to the gate structure 2452 through at least one via structures 2493. The gate structure 2452 can serve as the active gate terminal of the ROM cell 2420, while the gate structure 2451 can serve as the inactive gate terminal of the ROM cell 220. Similarly, the M0 track 2474 (WL1) can also extend along the X-direction to couple to the ROM cell 2430. For example, the M0 track 2474 is coupled to the gate structure 2453 through at least one via structures 2493. The gate structure 2453 can serve as the active gate terminal of the ROM cell 2430, while the gate structure 2454 can serve as the inactive gate terminal of the ROM cell 2430.

Referring next to FIG. 25, the hybrid cross-sectional view includes a plural number of cross-sectional views of the memory array 2410, each of which is cut along line AA′ (indicated in FIG. 24). As shown in FIG. 25, the epitaxial structure 2440A is replaced by the dielectric structure 2480, which causes one of the source/drain terminals of the ROM cell 2420 to be electrically isolated from the interconnect structure 2472 (VSS). The channel of the active second sub-transistor (e.g., nanostructures 2520B overlaid or wrapped by the gate structure 2452) has one end in direct contact with the dielectric structure 2480, with the other end electrically coupled to the epitaxial structures 2440B-C. Equivalently, the ROM cell 2420 has one of its source/drain terminals disconnected from the interconnect structure 2472 (VSS) and the other source/drain terminal coupled to the interconnect structure 2471 (BL). As a result, the ROM cell 2420 may conduct a first current, a level of which is relatively low or close to zero. It should be noted that the channel of the inactive first sub-transistor (e.g., nanostructures overlaid by the gate structure 2451 that has not been replaced by a dielectric material) may be later removed during the formation of the dielectric gate structure 2451.

FIG. 26 further illustrates another cross-sectional view of the memory array 2410 cut along line BB′ (indicated in FIG. 24). For example, the cross-sectional view of FIG. 26 is cut along the dielectric structure 2480. As shown, the dielectric structure 2480 may have a whole of its top surface in contact with a bottom surface of the MD 2461, while a top surface of the MD 2461 is electrically connected to the interconnect structure 2472 (VSS) through one of the via structures 2491. In some embodiments, the dielectric structure 2480 may have its sidewalls each in contact with no epitaxial structure. Such sidewalls of the dielectric structure 2480 can face the Y-direction. Stated another way, the MD 2461 has no portion in contact with an epitaxial structure.

Referring again to FIG. 25, the epitaxial structures 2440D retains, which causes one of the source/drain terminals of the ROM cell 2430 to be electrically couped to the interconnect structure 2472 (VSS). The channel of the active second sub-transistor (e.g., nanostructures 2530B overlaid or wrapped by the gate structure 2453) has one end electrically coupled to the epitaxial structures 2440B-C, with the other end electrically coupled to the epitaxial structure 2440D. Equivalently, the ROM cell 2430 has one of its source/drain terminals coupled to the interconnect structure 2472 (VSS) and the other source/drain terminal coupled to the interconnect structure 2471 (BL). As a result, the ROM cell 2430 may conduct a second current, a level of which is relatively high. It should be noted that the channel of the inactive first sub-transistor (e.g., nanostructures overlaid by the gate structure 2454 that has not been replaced by a dielectric material) may be later removed during the formation of the dielectric gate structure 2454.

FIG. 27 further another cross-sectional view of the memory array 2410 cut along line CC′ (indicated in FIG. 24). For example, the cross-sectional view of FIG. 27 is cut along the epitaxial structure 2440D. As shown, the epitaxial structure 2440D may have a whole of its top surface in contact with a bottom surface of the MD 2463, and a top surface of the MD 2463 is electrically connected to the interconnect structure 2472 (VSS) through one of the via structures 2491. In some embodiments, a whole of the epitaxial structure 2440D is electrically coupled to the MD 2463. Stated another way, the MD 2463 has a portion with a width along the Y-direction (WA) in contact with the epitaxial structure 2440D, or the epitaxial structure 2440D has a width along the Y-direction (WA) in contact with the MD 2463.

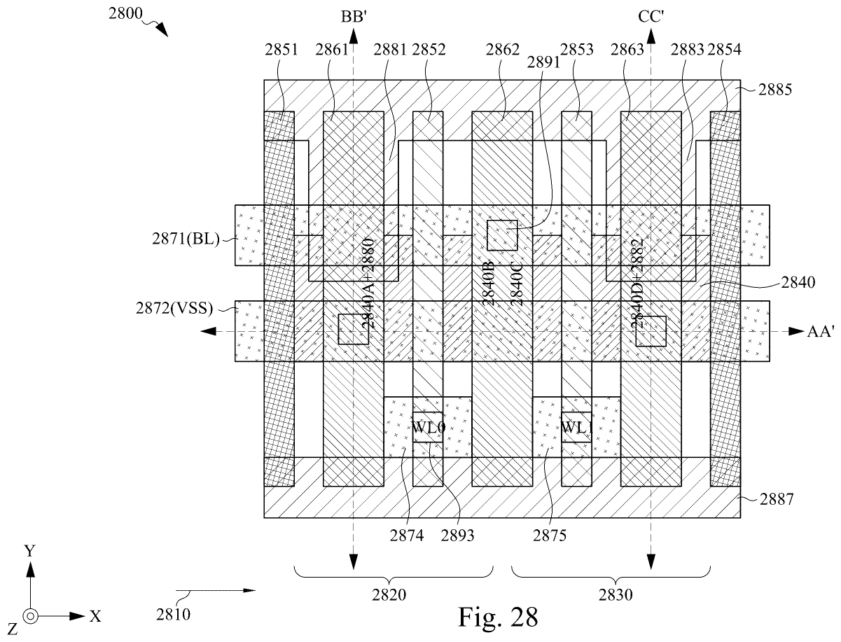

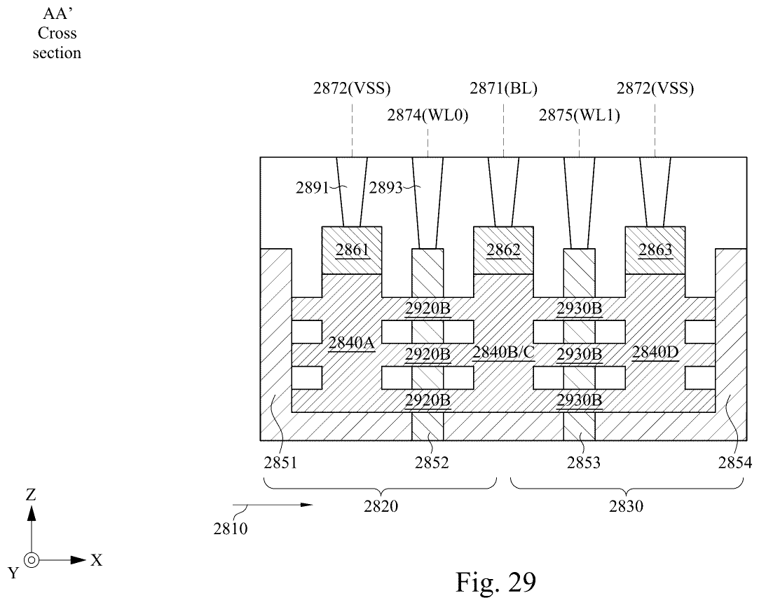

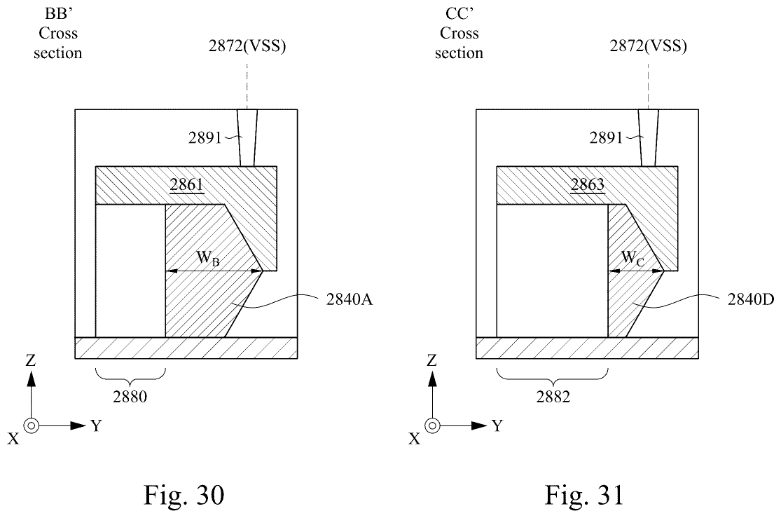

FIG. 28 illustrates an example layout 2800 configured to form (or program) a memory array 2810 including ROM cells, 2820 and 2830, that present a first logic state and a second logic state, respectively, in accordance with some embodiments. Further, FIG. 29 illustrates a hybrid cross-sectional view of the memory array 2810, FIG. 30 illustrates a cross-sectional view of the ROM cell 2820, and FIG. 31 illustrates a cross-sectional view of the ROM cell 2830. It should be understood that the layout 2800 of FIG. 28 and the corresponding cross-sectional views of FIGS. 29-31 are provided merely for illustrative purposes, and are not intended to limit the scope of the present disclosure.

Referring to FIG. 28, the layout 2800 includes patterns for forming an active region 2840, gate structures 2851, 2852, 2853, and 2854, respectively. It should be understood that the layout 2800 can include any number of other patterns to form respective active regions or gate structures, while remaining within the scope of present disclosure. In some embodiments, the active region 2840 can extend along a first lateral direction (e.g., the X-direction), and the gate structures 2851 to 2854 can each extend along a second lateral direction (e.g., the Y-direction) perpendicular to the first lateral direction. The gate structures 2851 to 2854 can each traverse the active region 2840. In some embodiments, the gate structures 2852 and 2853 can each correspond to an active (e.g., metal) gate structure, while the gate structures 2851 and 2854 can each correspond to an inactive (e.g., dielectric) gate structures. For example, the gate structures 2851 to 2854 can define respective footprints of several later formed gate structures, in which the gate structures 2852 and 2853 may each be formed as a metal gate structure and the gate structures 2851 and 2854 may each be formed as a dielectric gate structure. In some embodiments, the metal gate structure can include a gate dielectric (e.g., a high-k material) and a gate metal (e.g., one or more work function metal materials), while the dielectric gate structure may be formed of a dielectric material. In some embodiments, the dielectric gate structure (e.g., 2851, 2854) may first be formed as a poly-silicon gate structure and then be replaced with a dielectric material.

In some embodiments, the ROM cells of the memory array 2810 (e.g., 2820, 2830) may each be formed as a gate-all-around (GAA) transistor. However, the ROM cells of the memory array (formed by the layout 2800) can be formed as any of various other transistor structure while remaining within the scope of the present disclosure. In the example of GAA transistor structures, the active region 2840 can be formed as a stack structure protruding from the frontside surface of a substrate. The stack includes a number of semiconductor nanostructures (e.g., nanosheets) extending along the X-direction and vertically separated from each other. Respective portions of the semiconductor structures in the stack that are overlaid by the gate structures 2851 to 2854 remain, while other portions are replaced with a number of epitaxial structures. The remaining portions of the semiconductor structures can be configured as the channel of a corresponding transistor, and the epitaxial structures coupled to both ends of the channel (e.g., along the X-direction) can be configured as source/drain structures (or terminals) of the transistor, and a portion of the gate structure that overlays (e.g., wraps around) the remaining portions of the semiconductor structures can be configured as a gate terminal of the transistor.

In FIG. 28, the active region 2840, together with the gate structures 2851 and 2852, can form the ROM cell 2820 with the above-described 1.5T configuration. For example, the portion of the active region 2840 overlaid by the gate structure 2851 may include a number of first nanostructures vertically separated from each other, which can collectively function as the channel of a first sub-transistor, and the portion of the active region 2840 overlaid by the gate structure 2852 may include a number of second nanostructures vertically separated from each other, which can collectively function as the channel of a second sub-transistor. In some embodiments, the gate terminal (e.g., 2851) of the first sub-transistor can later be replaced with a dielectric material, causing the first sub-transistor to remain turned-off, while the gate terminal (e.g., 2852) of the second sub-transistor can be coupled to a corresponding word line. Accordingly, the first ROM cell 2820 with a 1.5T configuration can be formed.

Further, the portions of the active region 2840 that are disposed on opposite sides of each of the gate structures 2852 and 2853 are replaced with epitaxial structures, respectively. Such epitaxial structures can function as source/drain terminals of the sub-transistors. For example, the gate structure 2852 can function as a gate terminal of the active second sub-transistor, while the gate structure 2851, replaced by a dielectric material, can function as a gate terminal of the inactive (or turned-off) first sub-transistor. Epitaxial structures, 2840A and 2840B, formed on the opposite sides of the gate structure 2852 can function as a first source/drain terminal and second source/drain terminal of the second sub-transistor. Similarly, the active region 2840, together with the gate structure 2853 and gate structure 2854, can form a second ROM cell 2830 in the same 1.5T configuration.

The layout 2800 further includes patterns for forming source/drain contact structures (sometimes referred to as MDs) 2861, 2862, and 2863, and interconnect structures 2871, 2872, 2873, and 2874, respectively. It should be understood that the layout 2800 can include any number of other patterns to form respective MDs or interconnect structures, while remaining within the scope of present disclosure. In some embodiments, the MDs 2861 to 2863 can each extend along the Y-direction, and the interconnect structures 2871 to 2874 can each extend along the X-direction. The MDs 2861 to 2863 can each be in electrical contact with a corresponding epitaxial structure (the source/drain terminal of a transistor or sub-transistor). The interconnect structures 2871 to 2874 can each be electrically coupled to one or more corresponding gate structures or one or more corresponding MDs.

In some embodiments, after forming the epitaxial structures 2840A to 2840D and prior to forming the MDs 2861 to 2863, at least a portion of the epitaxial structure 2840A can be replaced with a vertical dielectric structure 2880 (which can be better seen in the cross-sectional views of FIGS. 29 and 30) and at least a portion of the epitaxial structure 2840D can be replaced with a vertical dielectric structure 2882 (which can be better seen in the cross-sectional views of FIGS. 29 and 31), while other epitaxial structures 2840B-C may remain substantially intact.

For example, ⅓ of the epitaxial structure 2840A may be replaced with the dielectric structure 2880. This can cause the channel of the second sub-transistor of the ROM cell 2820 (e.g., the nanostructures overlaid by the gate structure 2852) to have one of its ends to directly contact a combination of the dielectric structure 2880 and the remaining portion of the epitaxial structure 2840A (e.g., ⅔ of the epitaxial structure 2840A). In another example, ⅔ of the epitaxial structure 2840D may be replaced with the dielectric structure 2882. This can cause the channel of the second sub-transistor of the ROM cell 2830 (e.g., the nanostructures overlaid by the gate structure 2853) to have one of its ends to directly contact a combination of the dielectric structure 2882 and the remaining portion of the epitaxial structure 2840D (e.g., ⅓ of the epitaxial structure 2840D).

Such a removal process and a replacement process can be performed based on cut patterns 2881 and 2883 included in the layout 2800. For example, the cut pattern 2881 can extend along the Y-direction and be formed wider than or equal to the corresponding MD 2861 in the X-direction. Further, the cut pattern 2881 can overlay ½ of the epitaxial structure 2840A. For another example, the cut pattern 2883 can extend along the Y-direction and be formed wider than or equal to the corresponding MD 2863 in the X-direction. Further, the cut pattern 2883 can overlay ⅔ of the epitaxial structure 2840D. Following the cut pattern 2881, ½ of the epitaxial structure 2840A can be removed (e.g., anisotropically etched) and the removed portion can be filled with a dielectric material to form the dielectric structure 2880. Similarly, following the cut pattern 2883, ⅔ of the epitaxial structure 2840D can be removed (e.g., anisotropically etched) and the removed portion can be filled with a dielectric material to form the dielectric structure 2882.

As such, the MD 2861 is (e.g., physically) coupled to the dielectric structure 2880 and the ⅔ of the epitaxial structure 2840A combined, causing any conductive structure formed above (and electrically connected to) the MD 2861 to be electrically coupled to the ⅔ of the epitaxial structure 2840A. Stated another way, the MD 2861 is electrically connected to one of the source/drain terminals of the ROM cell 2820 (or the first source/drain terminal of the second sub-transistor of the ROM cell 2820). Similarly, the MD 2863 is (e.g., physically) coupled to the dielectric structure 2882 and the ⅓ of the epitaxial structure 2840D combined, causing any conductive structure formed above (and electrically connected to) the MD 2863 to be electrically coupled to the ⅓ of the epitaxial structure 2840D. Stated another way, the MD 2863 is electrically connected to one of the source/drain terminals of the ROM cell 2830 (or the first source/drain terminal of the second sub-transistor of the ROM cell 2830). The cut patterns 2881 and 2883 can each be coupled to one of other cut pattern 2885 or 2887 that extends along the X-direction, as shown in FIG. 28. For example, both of the cut patterns 2881 and 2883 have one of their ends connected to the cut pattern 2885. The cut patterns 2885 and 2887 can be configured to cut one or more of the gate structures 2851 to 2854 (into multiple segments), in some embodiments.

The interconnect structures 2871 to 2874 can each be formed as a metal track in one of plural metallization layers disposed over the frontside surface of the substrate, or over the MDs 2861-2874 and the gate structures 2851-2854. Each of the metallization layers can include (e.g., embed) a plural number of metal tracks in one or more dielectric layers (e.g., formed of an oxide material or a low-k dielectric material). In some embodiments, the interconnect structures 2871 to 2874 may be formed in a bottommost one of the metallization layers. Such a bottommost metallization layer is sometimes referred to as an M0 layer, and accordingly, a metal track included in the M0 layer is sometimes referred to as an M0 track. Further, in some embodiments, the M0 track 2871 can operatively serve as a bit line (BL) or a portion of the BL for the memory array 2810, the M0 track 2872 can operatively serve as a power rail carrying a ground voltage (VSS) or a portion of the power rail for the memory array 2810, the M0 track 2873 can operatively serve as a word line (WL0) or a portion of the WL0 for the memory array 2810, and the M0 track 2874 can operatively serve as another word line (WL1) or a portion of the WL1 for the memory array 2810.

The M0 track 2871 (BL) can extend along the X-direction to couple to at least the ROM cells 2820 and 2830. For example, the M0 track 2871 is coupled to the MD 2862 through via structure 2891. The MD 2862 is electrically coupled to one of the source/drain terminals of the ROM cell 2820 (e.g., the epitaxial structure 2840B), and one of the source/drain terminals of the ROM cell 2830 (e.g., the epitaxial structure 2840C), in which the epitaxial structures 2840B and 2840C are merged. The M0 track 2872 (VSS) can also extend along the X-direction to couple to at least the ROM cells 2820 and 2830. For example, the M0 track 2872 is coupled to the MDs 2861 and 2863 through multiple via structures 2891, respectively. The MD 2861 is physically and electrically coupled to the other source/drain terminal of the ROM cell 2820 (e.g., the remaining ⅔ of the epitaxial structure 2840A), and the MD 2863 is physically and electrically coupled to the other source/drain terminal of the ROM cell 2830 (e.g., the remaining ⅓ of the epitaxial structure 2840D).

The M0 track 2873 (WL0) can also extend along the X-direction to couple to the ROM cell 2820. For example, the M0 track 2873 is coupled to the gate structure 2852 through via structure 2893. The gate structure 2852 can serve as the gate terminal of the ROM cell 2820, while the gate structure 2851 may operate as an inactive gate terminal of the ROM cell 2820. Similarly, the M0 track 2874 (WL1) can also extend along the X-direction to couple to the ROM cell 2830. For example, the M0 track 2874 is coupled to the gate structure 2853 through via structure 2893. The gate structure 2853 can serve as the gate terminal of the ROM cell 2830, while the gate structure 2854 may operate as an inactive gate terminal of the ROM cell 2830.

Referring next to FIG. 29, the hybrid cross-sectional view includes a plural number of cross-sectional views of the memory array 2810, each of which is cut along line AA′ (indicated in FIG. 28). As shown in FIG. 29, the epitaxial structure 2840A still have a portion retained and in contact with the dielectric structure 2880 (FIG. 30), which causes one of the source/drain terminals of the second sub-transistor of the ROM cell 2820 to remain electrically coupled to the interconnect structure 2872 (VSS). The channel of the second sub-transistor (e.g., nanostructures 2920B overlaid or wrapped by the gate structure 2852) has one end electrically coupled to the remaining portion of the epitaxial structure 2840A and the dielectric structure 2880, with the other end electrically coupled to the epitaxial structures 2840B-C. Equivalently, the ROM cell 2820 has one of its source/drain terminals, with a reduced portion (e.g., ⅔ of the original size), coupled to the interconnect structure 2872 (VSS) and the other source/drain terminal coupled to the interconnect structure 2871 (BL). As a result, the ROM cell 2820 may conduct a third current, a level of which is higher than the first current (flowing through the ROM cell 2420 of FIGS. 24-27) and lower than the second current (flowing through the ROM cell 2430 of FIGS. 24-27).

FIG. 30 further illustrates another cross-sectional view of the memory array 2810 cut along line BB′ (indicated in FIG. 28). For example, the cross-sectional view of FIG. 30 is cut along the dielectric structure 2880 and the epitaxial structure 2840A. As shown, the epitaxial structure 2840A may have a sidewall (facing the Y-direction) in contact with the dielectric structure 2880. Respective top surfaces of the dielectric structure 2880 and the epitaxial structure 2840A may be in contact with a bottom surface of the MD 2861, while a top surface of the MD 2861 is electrically connected to the interconnect structure 2872 (VSS) through one of the via structures 2891. In some embodiments, the MD 2861 has a portion with a width along the Y-direction (W_{B}) in contact with the (remaining) epitaxial structure 2840A, or the (remaining) epitaxial structure 2840A has a width along the Y-direction (WB) in contact with the MID 2861.

Referring again to FIG. 29, the epitaxial structure 2840D still has a portion retained and in contact with the dielectric structure 2882 (FIG. 31), which causes one of the source/drain terminals of the second sub-transistor of the ROM cell 2830 to remain electrically coupled to the interconnect structure 2872 (VSS). The channel of the second sub-transistor (e.g., nanostructures 2930B overlaid or wrapped by the gate structure 2853) has one end electrically coupled to the remaining portion of the epitaxial structure 2840D and the dielectric structure 2882, with the other end electrically coupled to the epitaxial structures 2840B-C. Equivalently, the ROM cell 2830 has one of its source/drain terminals, with a reduced portion (e.g., ⅓ of the original size), coupled to the interconnect structure 2872 (VSS) and the other source/drain terminal coupled to the interconnect structure 2871 (BL). As a result, the ROM cell 2830 may conduct a fourth current, a level of which is higher than the first current (flowing through the ROM cell 2420 of FIGS. 24-27) and lower than the third current (flowing through the ROM cell 2820 of FIGS. 27-31).

FIG. 31 further illustrates another cross-sectional view of the memory array 2810 cut along line CC′ (indicated in FIG. 28). For example, the cross-sectional view of FIG. 31 is cut along the dielectric structure 2882 and the epitaxial structure 2840D. As shown, the epitaxial structure 2840D may have a sidewall (facing the Y-direction) in contact with the dielectric structure 2882. Respective top surfaces of the dielectric structure 2882 and the epitaxial structure 2840D may be in contact with a bottom surface of the MD 2863, while a top surface of the MD 2863 is electrically connected to the interconnect structure 2872 (VSS) through one of the via structures 2891. In some embodiments, the MD 2863 has a portion with a width along the Y-direction (W_{C}) in contact with the (remaining) epitaxial structure 2840D, or the (remaining) epitaxial structure 2840D has a width along the Y-direction (W_{C}) in contact with the MD 2863.

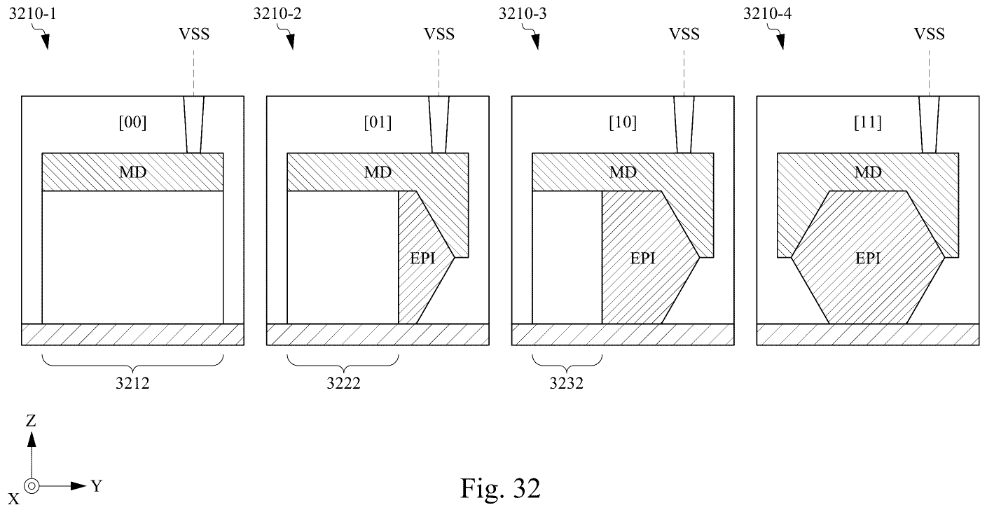

FIG. 32 illustrates four different logic states, [00], [01], [10], and [11], presented by ROM cells, 3210-1, 3210-2, 3210-3, and 3210-4, respectively, in accordance with some embodiments. As shown, the ROM cells 3210-1 to 3210-4 each have at least one of its epitaxial structures with a respective width in the Y-direction to contact an MD, which is further coupled to an interconnect structure configured as a power rail carrying a ground voltage (e.g., VSS). In some embodiments, by connecting different sizes of the epitaxial structures to VSS, the ROM cells 3210-1 to 3210-4 may be referred to as being programed through or coded on VSS.

For example, the ROM cell 3210-1 has one source/drain terminal replaced by a vertical dielectric structure 3212 and the other source/drain terminal retained, similar to the ROM cell 2420 (FIG. 24); the ROM cell 3210-2 has one source/drain terminal with ⅔ replaced by a vertical dielectric structure 3222 and the other source/drain terminal retained, similar to the ROM cell 2830 (FIG. 28); the ROM cell 3210-3 has one source/drain terminal with ⅓ replaced by a vertical dielectric structure 3232 and the other source/drain terminal retained, similar to the ROM cell 2820 (FIG. 28); and the ROM cell 3210-4 has both of its source/drain terminals retained, similar to the ROM cell 2430 (FIG. 24). As such, the ROM cells 3210-1, 3210-2, 3210-3, and 3210-4 can conduct four differentiable currents. For example, the ROM cell 3210-4 can conduct the highest current, the ROM cell 3210-3 can conduct the next highest current, the ROM cell 3210-2 can conduct the next lowest current, and the ROM cell 3210-1 can conduct the lowest current, causing the ROM cells 3210-4, 3210-3, 3210-2, and 3210-1 to present four different logic states, [11], [10], [01], and [00], respectively.

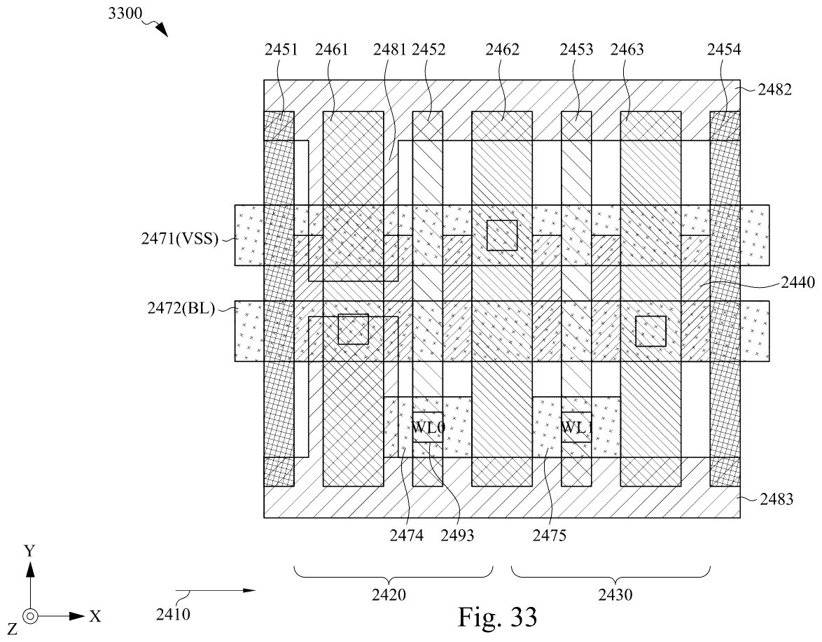

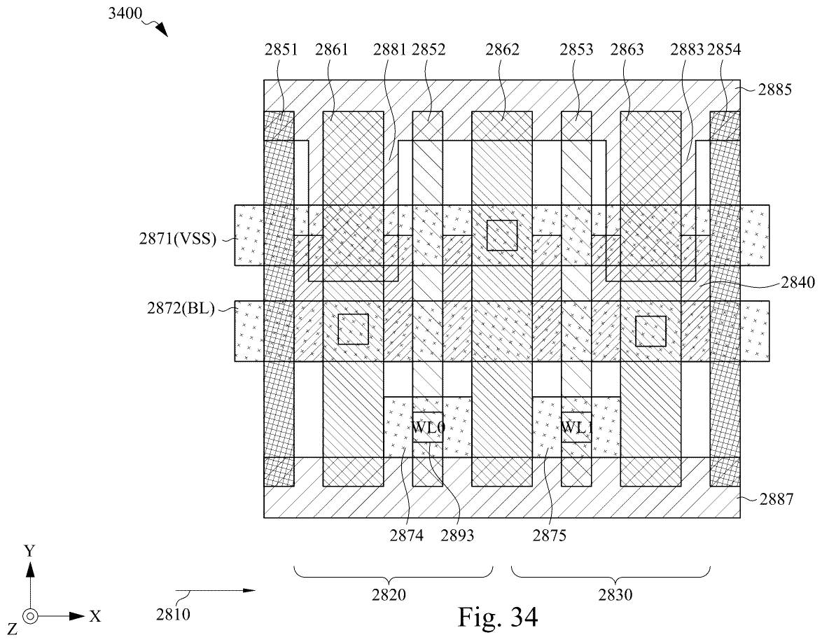

FIG. 33 and FIG. 34 illustrate example layouts 3300 and 3400, respectively, each of which is configured to form (or program) a memory array including two ROM cells that respectively present different logic states, in accordance with some embodiments. The layouts 3300 and 3400 are substantially similar to the layout 2400 (FIG. 24) and layout 2800 (FIG. 28), respectively, except that the functionalities of the interconnect structures 2471 and 2472 are switched in the layout 3300 and the functionalities of the interconnect structures 2871 and 2872 are switched in the layout 3400. Accordingly, the reference numerals of FIG. 24 and FIG. 28 are reused in the following discussion of FIG. 33 and FIG. 34, respectively.

Referring first to FIG. 33, similar to the layout 2400, the layout 3300 includes the patterns for forming the active region 2440, the gate structures 2451 to 2454, the MDs 2461 to 2463, and the M0 tracks 2471 to 2474, and the cut patterns 2481 to 2483. However, according to the layout 3300, the M0 tracks 2471 and 2472 are configured as the power rail carrying VSS and the BL, respectively. As such, the ROM cell 2420 may have one of its source/drain terminals replaced by a dielectric structure which is electrically isolated from the BL, and the ROM cell 2430 may have its source/drain terminals electrically coupled to the BL and VSS, respectively. The ROM cells 2420 and 2430, formed based on the layout 3300, may thus be referred to as being programed through or coded on BL.

Referring next to FIG. 34, the layout 3400, similar to the layout 2800, includes the patterns for forming the active region 2840, the gate structures 2851 to 2854, the MDs 2861 to 2863, and the M0 tracks 2871 to 2874, and the cut patterns 2881 to 2887. However, according to the layout 3400, the M0 tracks 2871 and 2872 are configured as the power rail carrying VSS and the BL, respectively. As such, the ROM cell 2820 may have one of its source/drain terminals partially replaced by a dielectric structure and electrically coupled to the BL, and the ROM cell 2830 may have its source/drain terminals partially replaced by another dielectric structure and electrically coupled to the BL. The ROM cells 2820 and 2830, formed based on the layout 3400, may thus be referred to as being programed through or coded on BL.

In addition to varying the widths of epitaxial structures (as discussed above), other sizes of the epitaxial structures (source/drain terminals) can be tailored to cause the respective ROM cells of a memory array to conduct different current levels, thereby presenting different logic states. With the different heights, the epitaxial structures of the ROM cells can each be electrically coupled to a respective number of nanostructures. Stated another way, each of the ROM cells can have its channel constituted by a respective number of nanostructures.

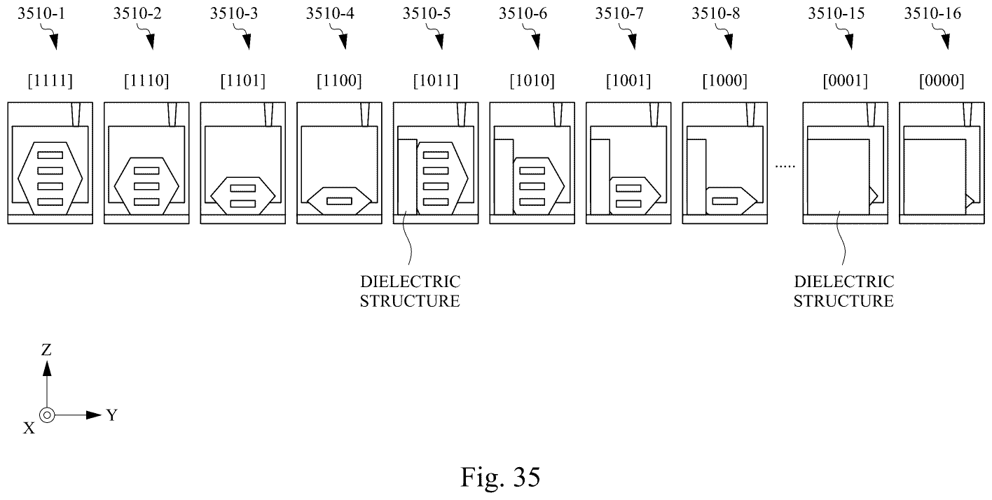

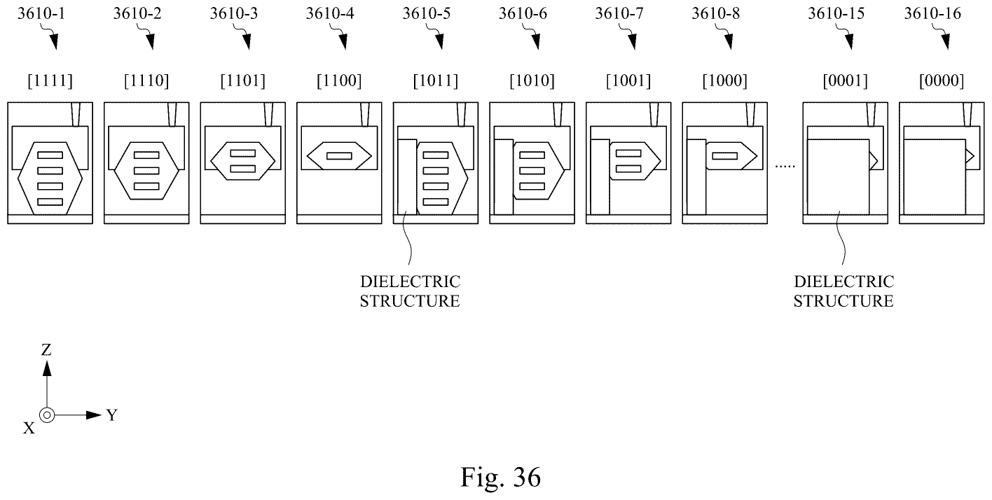

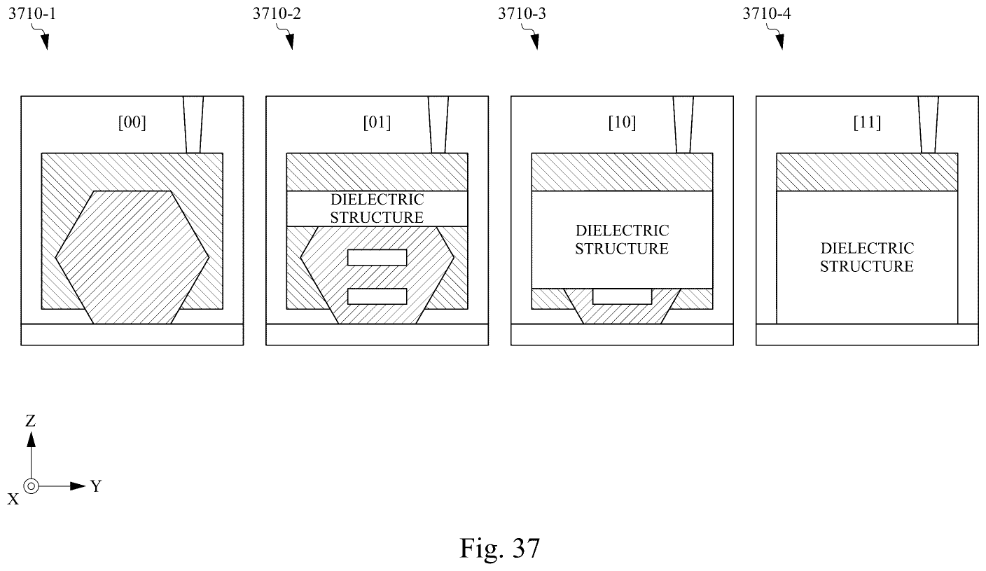

For example, by forming the epitaxial structures with four different heights, the ROM cells of a memory array can present four logic states such as, ROM cells 3510-1, 3510-2, 3510-3, and 3510-4 of FIG. 35, and ROM cells 3610-1, 3610-2, 3610-3, and 3610-4 of FIG. 36. As another example, by forming the epitaxial structures with four different heights and with four different widths, the ROM cells of a memory array can present sixteen logic states such as, ROM cells 3510-1 to 3510-16 of FIG. 35, and ROM cells 3610-1 to 3610-16 of FIG. 36. In the examples of FIGS. 35-36, portions of some of the epitaxial structures are each replaced by a vertical dielectric structure, e.g., each of these epitaxial structures having a sidewall contacting the corresponding dielectric structure. As yet another example, by forming the epitaxial structures with four different heights, the ROM cells of a memory array can present four logic states such as, ROM cells 3710-1, 3710-2, 3710-3, and 3710-4 of FIG. 37. In the example of FIG. 37, portions of some of the epitaxial structures are each replaced by a lateral dielectric structure, e.g., each of these epitaxial structures having a top surface contacting the corresponding dielectric structure.

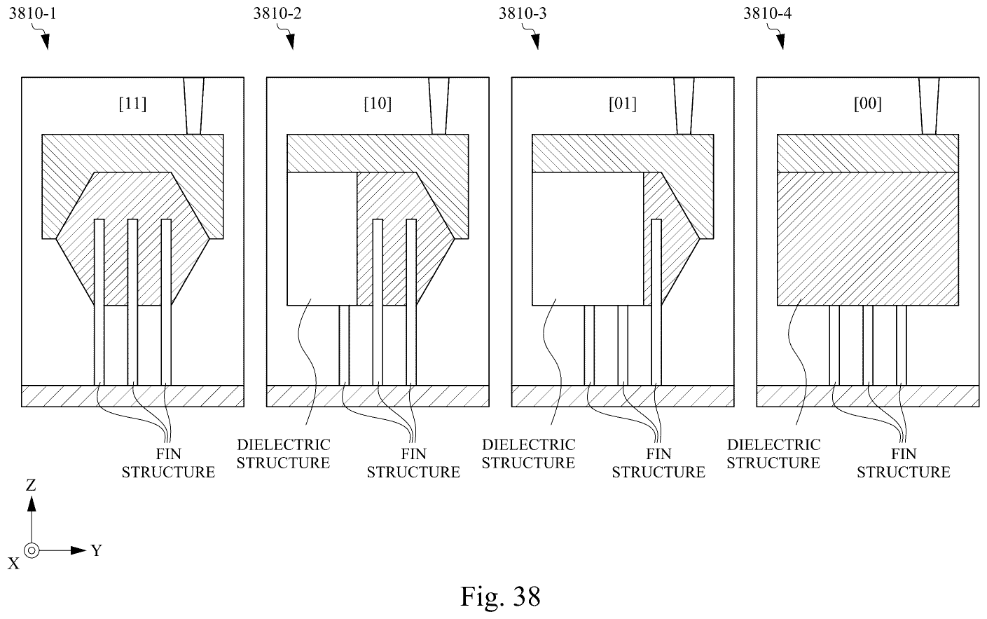

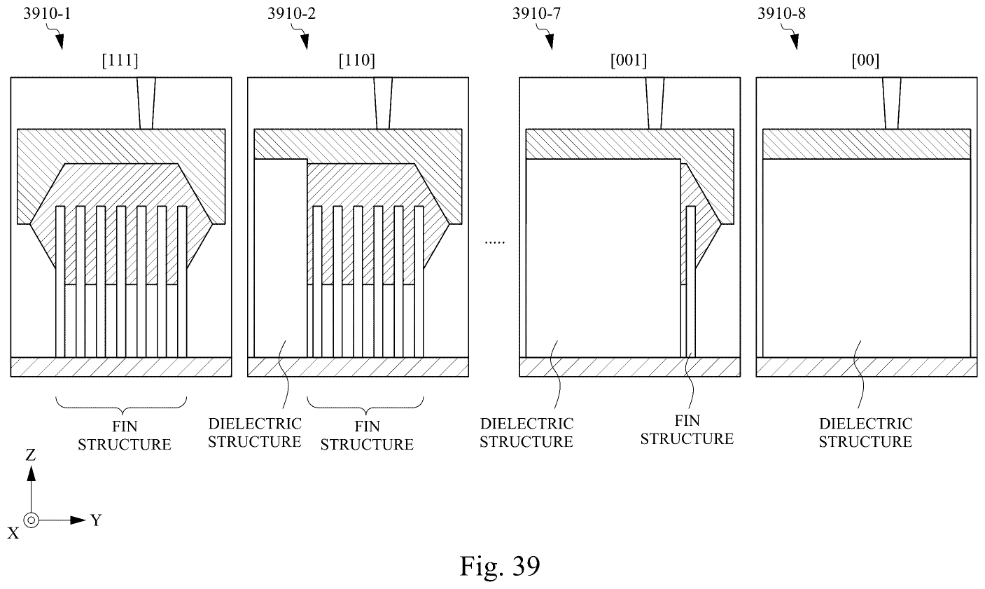

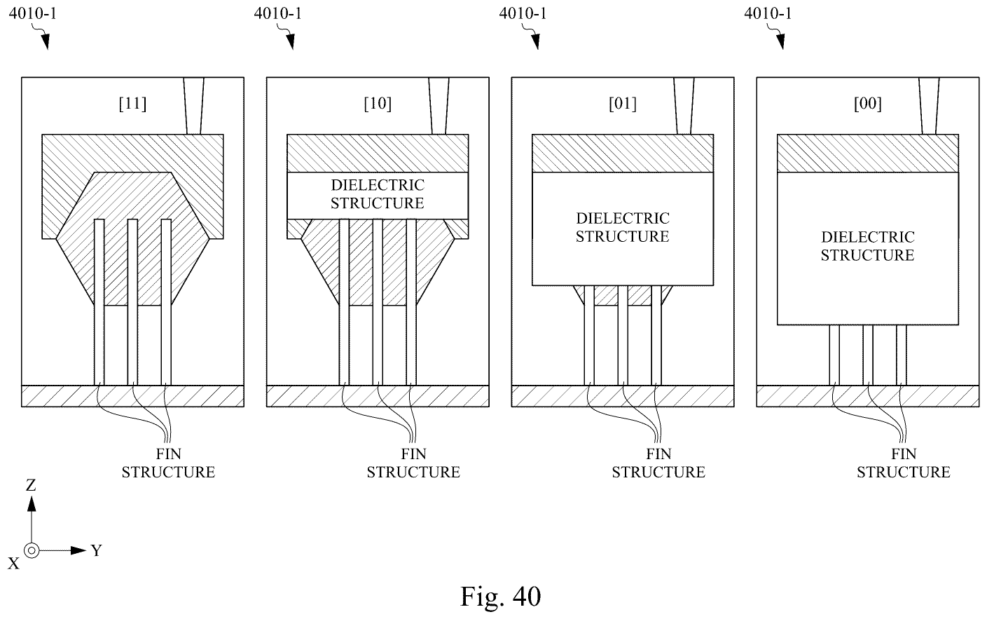

As noted above, each of the ROM cells can be formed in any of various other transistor structures while remaining within the scope of the present disclosure. For example, the ROM cells of the currently disclosed memory array can be formed with a FinFET structure. With such a FinFET structure, in one embodiment, the epitaxial structure (source/drain terminal) of an ROM cell can be tailored to have a width in the Y-direction to electrically couple to a respective number of fin structures (collectively serving as a channel). The width of the epitaxial structure can be tailored through forming a vertical dielectric structure in contact with a remaining portion of the epitaxial structure. Accordingly, the ROM cells with their epitaxial structures having different widths can present respective logic states such as, ROM cells 3810-1, 3810-2, 3810-3, and 3810-4 of FIG. 38, and ROM cells 3910-1, 3910-2. 3910-7, and 3910-8 of FIG. 39. In another embodiment, the epitaxial structure (source/drain terminal) of an ROM cell can be tailored to have a height in the Z-direction to electrically couple to a fixed number of fin structures (collectively serving as a channel). The height of the epitaxial structure can be tailored through forming a lateral dielectric structure in contact with a remaining portion of the epitaxial structure. Accordingly, the ROM cells with their epitaxial structures having different heights can present respective logic states such as, ROM cells 4010-1, 4010-2, 4010-3, and 4010-4 of FIG. 40.

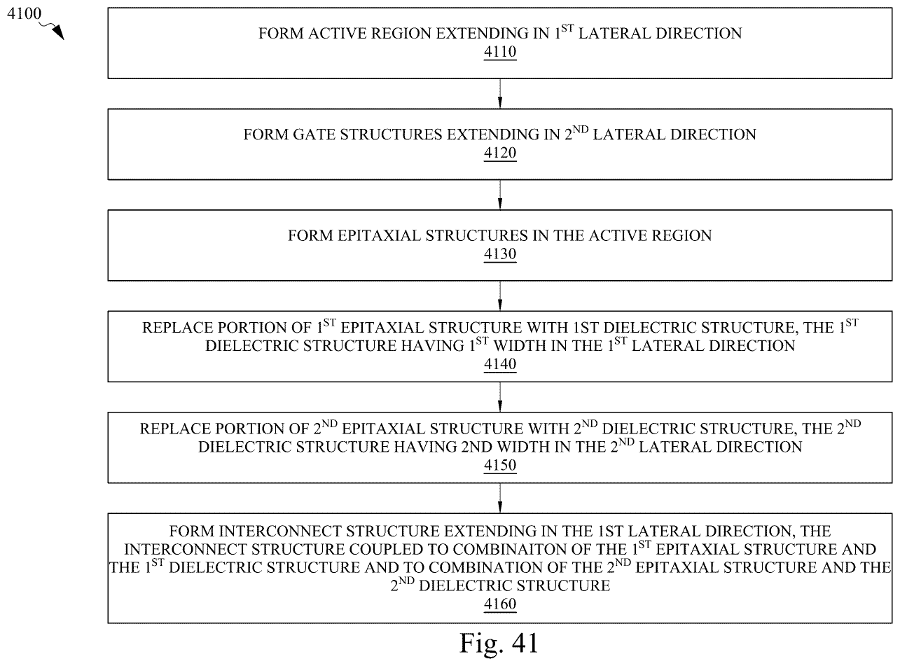

FIG. 41 illustrates a flow chart of an example method 4100 for forming a memory device (e.g., a memory array), in accordance with various embodiments of the present disclosure. In some embodiments, the memory array can be formed based on the layout 200 (FIGS. 2), 600 (FIGS. 6), 1100 (FIGS. 11), 1200 (FIGS. 12), 1300 (FIGS. 13), 1700 (FIGS. 17), 2200 (FIGS. 22), 2300 (FIGS. 23), 2800 (FIGS. 28), 3300 (FIG. 33), and/or 3400 (FIG. 34) so as to have one or more of its memory cells programmed with a logic state different from other memory cells by tailoring the respective sizes of their epitaxial structures (source/drain terminals). Accordingly, the following discussion of the method 4100 may refer to some of the above figures. It should be noted that the method 4100 as shown in FIG. 41 is merely an example, and is not intended to limit the present disclosure. Thus, it is understood that the order of the operations of the method 4100 of FIG. 41 can be changed, for example, additional operations may be provided before, during, and after the method 4100, and that some operations may only be described briefly herein.

The method 4100 starts with operation 4110 of forming an active region extending along a first lateral direction. Using the layout 600 (FIG. 6) as a representative example, the active region 640, extending the X-direction, can be formed over a semiconductor substrate. In an example, the active region 640 can be formed as a stack of first semiconductor layers (e.g., SiGe) and second semiconductor layers (e.g., Si) alternately staked on top of one another, where the first semiconductor layers may later be replaced as the gate structure of a GAA transistor and the second semiconductor layers may be configured as a channel of the GAA transistor. In another example, the active region 640 can be formed as a number of fin structures protruding from the semiconductor substrate, where the fin structures may be configured as the channel of a FinFET.

The method 4100 continues to operation 4120 of forming a plurality of gate structures over the active region, each of the gate structures extending along a second lateral direction perpendicular to the first lateral direction. Continuing with the above example of FIG. 6, the gate structures can be 651 to 656, extending in the Y-direction, can be formed over the active region 640. Each of the gate structures 651 to 656 can traverse the active region 640. In an example, the gate structures 651 to 656 may be first formed as poly-silicon (e.g., dummy) gate structures and later be replaced with metal gate structures, respectively.

The method 4100 continues to operation 4130 of forming a plurality of epitaxial structures in the active region, each of the gate structures interposed between adjacent ones of the epitaxial structures. In some embodiments, the active region, the gate structures, and the epitaxial structure can operatively form a plurality of memory cells (e.g., ROM cells). Still with the same example of FIG. 6, after forming the (e.g. dummy) gate structures 651 to 656, portions of the active region 640 that are not overlaid by the gate structures 651 to 656 are replaced with the epitaxial structures 640A to 640H. In the example layout of FIG. 6 where each memory cell is formed with a 2T configuration, each memory cell (e.g., 620, 630) may be formed as two sub-transistors coupled in parallel, one of which is formed by a first one of the gate structures (e.g., 652) and the epitaxial structures (e.g., 640A and 640B) disposed on its opposite sides and the other of which is formed by a second one of the gate structures (e.g., 653) and the epitaxial structures (e.g., 640C and 640D) disposed on its opposite sides.

The method 4100 continues to operation 4140 of replacing a portion of a first one of the epitaxial structures with a first dielectric structure, wherein the first dielectric structure has a first width extending along the second lateral direction. In the same example of FIG. 6, a portion of the epitaxial structures 640B-C is replaced with the dielectric structure 680. The dielectric structure 680 may extend in a vertical direction, and thus, a sidewall of the dielectric structures 680 (facing the second lateral direction) can be in contact with a remaining portion of the epitaxial structures 640B-C. As a result, the remaining portion of the epitaxial structures 640B-C can have a tailored (e.g., reduced) width in the second lateral direction. In some embodiments, the dielectric structure 680 may be formed by at least some of the process steps: exposing the epitaxial structures 640B-C based on a corresponding cut pattern (e.g., 681); performing one or more anisotropic etching processes to remove the exposed portion of the epitaxial structures 640B-C (thereby forming a vertical trench or recess); filling the trench with a dielectric material; and optionally performing a polishing process.

The method 4100 continues to operation 4150 of replacing a portion of a second one of the epitaxial structures with a second dielectric structure, wherein the second dielectric structure has a second width extending along the second lateral direction. In the same example of FIG. 6, a portion of the epitaxial structures 640F-G is replaced with the dielectric structure 682. The dielectric structure 682 may extend in a vertical direction, and thus, a sidewall of the dielectric structures 682 (facing the second lateral direction) can be in contact with a remaining portion of the epitaxial structures 640F-G. As a result, the remaining portion of the epitaxial structures 640F-G can have a tailored (e.g., reduced) width in the second lateral direction. In some embodiments, the dielectric structure 682 may be formed by at least some of the process steps: exposing the epitaxial structures 640F-G based on a corresponding cut pattern (e.g., 683); performing one or more anisotropic etching processes to remove the exposed portion of the epitaxial structures 640F-G (thereby forming a vertical trench or recess); filling the trench with a dielectric material; and optionally performing a polishing process.

The method 4100 continues to operation 4160 of forming an interconnect structure extending along the first lateral direction, wherein the interconnect structure is physically coupled to the first dielectric structure and a remaining portion of the first epitaxial structure, and physically coupled to the second dielectric structure and a remaining portion of the second epitaxial structure. In some embodiments, the interconnect structure can be operatively configured as a bit line (BL) or a power rail carrying a ground voltage (e.g., VSS). When configured as the BL, the memory cells may be referred to as being coded on BL; and when configured as carrying VSS, the memory cells may be referred to as being coded on VSS. Continuing with the same example of FIG. 6, the interconnect structure 672 is configured to carry VSS, which causes the interconnect structure 672 to operatively couple to the combination of epitaxial structures 640B-C and the dielectric structure 680 of the ROM cell 620 and to the combination of epitaxial structures 640F-G and the dielectric structure 682 of the ROM cell 630, respectively. With the different remaining widths (in the Y-direction), the ROM cell 620 and ROM cell 630 can conduct different current levels, which results in presenting different logic states.

In one aspect of the present disclosure, a memory device is disclosed. The memory device includes a plurality of memory cells, each of the plurality of memory cells configured to store one or more data bits; a first interconnect structure operatively configured as a bit line and coupled to each of the plurality of memory cells, the first interconnect structure extending along a first lateral direction; and a second interconnect structure operatively configured to carry a supply voltage and coupled to each of the plurality of memory cells, the second interconnect structure extending along the first lateral direction. The one or more data bits stored by a first one of the plurality of memory cells correspond to a first logic state, the first memory cell includes a first epitaxial structure with a nearly vertical sidewall in direct contact with a first dielectric structure, and the first epitaxial structure and the first dielectric structure are both coupled to either the first interconnect structure or the second interconnect structure.

In another aspect of the present disclosure, a memory device is disclosed. The memory device includes a plurality of memory cells being formed over an active region that extends along a first lateral direction; a first interconnect structure operatively configured as a bit line and extending along the first lateral direction; a second interconnect structure operatively configured as a power rail carrying a ground voltage and extending along the first lateral direction; and a plurality of epitaxial structures formed in the active region and coupled to either the first interconnect structure or the second interconnect structure. A first one of the plurality of epitaxial structures has a vertical sidewall in direct contact with a first dielectric structure, and wherein the vertical sidewall of the first epitaxial faces a second lateral direction perpendicular to the first lateral direction.

In yet another aspect of the present disclosure, a method for fabricating memory devices is disclosed. The method includes forming an active region extending along a first lateral direction. The method includes forming a plurality of gate structures over the active region, each of the gate structures extending along a second lateral direction perpendicular to the first lateral direction. The method includes forming a plurality of epitaxial structures in the active region, each of the gate structures interposed between adjacent ones of the epitaxial structures, wherein the active region, the gate structures, and the epitaxial structure operatively form a plurality of memory cells. The method includes replacing a first portion of a first one of the epitaxial structures with a first dielectric structure, wherein the first dielectric structure has a first width extending along the second lateral direction. The method includes replacing a second portion of a second one of the epitaxial structures with a second dielectric structure, wherein the second dielectric structure has a second width extending along the second lateral direction, and wherein the second width is different from the first width.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a plurality of memory cells, each of the plurality of memory cells configured to store one or more data bits;
a first interconnect structure operatively configured as a bit line and coupled to each of the plurality of memory cells, the first interconnect structure extending along a first lateral direction; and
a second interconnect structure operatively configured to carry a supply voltage and coupled to each of the plurality of memory cells, the second interconnect structure extending along the first lateral direction;
wherein the one or more data bits stored by a first one of the plurality of memory cells correspond to a first logic state, the first memory cell includes a first epitaxial structure with a nearly vertical sidewall in direct contact with a first dielectric structure, and the first epitaxial structure and the first dielectric structure are both coupled to either the first interconnect structure or the second interconnect structure.

2. The memory device of claim 1, wherein each of the plurality of memory cells is a read only memory (ROM) cell.

3. The memory device of claim 1, wherein the nearly vertical sidewall of the first epitaxial structure faces a second lateral direction perpendicular to the first lateral direction.

4. The memory device of claim 1, wherein the one or more data bits stored by a second one of the plurality of memory cells correspond to a second logic state, the second memory cell includes a second epitaxial structure with a nearly vertical sidewall in direct contact with a second dielectric structure, and the second epitaxial structure and the second dielectric structure are both coupled to either the first interconnect structure or the second interconnect structure.

5. The memory device of claim 4, wherein the second logic state is different from the first logic state.

6. The memory device of claim 5, wherein the first epitaxial structure has a first width extending along a second lateral direction perpendicular to the first lateral direction, and the second epitaxial structure has a second width extending along the second lateral direction, and wherein the first width is different from the second width.

7. The memory device of claim 5, wherein the first dielectric structure has a first width extending along a second lateral direction perpendicular to the first lateral direction, and the second dielectric structure has a second width extending along the second lateral direction, and wherein the first width is different from the second width.

8. The memory device of claim 4, the one or more data bits stored by a third one of the plurality of memory cells correspond to a third logic state different from the first or second logic state, and the third memory cell includes a third epitaxial structure with no nearly vertical sidewall coupled to either the first interconnect structure or the second interconnect structure.

9. The memory device of claim 8, the one or more data bit stored by a fourth one of the plurality of memory cells correspond to a fourth logic state different from the first, second, or third logic state, and the fourth memory cell includes no epitaxial structure coupled to either the first interconnect structure or the second interconnect structure.

10. The memory device of claim 1, wherein the first memory cell includes a first gate structure and a second gate structure sandwiching the first epitaxial structure, the first and second gate structures both extending along a second lateral direction perpendicular to the first lateral direction, and the first and second gate structures both configured as a word line.

11. The memory device of claim 1, wherein the first memory cell includes a first gate structure and a second gate structure sandwiching the first epitaxial structure, the first and second gate structures both extending along a second lateral direction perpendicular to the first lateral direction, and the first gate structure configured as a word line with the second gate structure operatively coupled to the supply voltage.

12. A memory device, comprising:
a plurality of memory cells being formed over an active region that extends along a first lateral direction;
a first interconnect structure operatively configured as a bit line and extending along the first lateral direction;
a second interconnect structure operatively configured as a power rail carrying a ground voltage and extending along the first lateral direction; and
a plurality of epitaxial structures formed in the active region and coupled to either the first interconnect structure or the second interconnect structure;
wherein a first one of the plurality of epitaxial structures has a vertical sidewall in direct contact with a first dielectric structure, and wherein the vertical sidewall of the first epitaxial structure faces a second lateral direction perpendicular to the first lateral direction.

13. The memory device of claim 12, wherein the first dielectric structure and the first epitaxial structure are both coupled to either the first interconnect structure or the second interconnect structure.

14. The memory device of claim 12, wherein at least a second one of the plurality of epitaxial structures has a vertical sidewall in direct contact with a second dielectric structure, wherein the vertical sidewall of the second epitaxial structure faces the second lateral direction.

15. The memory device of claim 14, wherein the first epitaxial structure has a first width extending in the second lateral direction and the second epitaxial structure has a second width extending in the second lateral direction different from the first width.

16. The memory device of claim 15, wherein the first epitaxial structure operatively forms a first one of the plurality of memory cells which presents a first logic state, and the second epitaxial structure operatively forms a second one of the plurality of memory cells which presents a second logic state different from the first logic state.

17. The memory device of claim 12, wherein each of the plurality of memory cells is a read only memory (ROM) cell.

18. A method for forming memory devices, comprising:
forming an active region extending along a first lateral direction;
forming a plurality of gate structures over the active region, each of the gate structures extending along a second lateral direction perpendicular to the first lateral direction;
forming a plurality of epitaxial structures in the active region, each of the gate structures interposed between adjacent ones of the epitaxial structures, wherein the active region, the gate structures, and the epitaxial structure operatively form a plurality of memory cells;
replacing a first portion of a first one of the epitaxial structures with a first dielectric structure, wherein the first dielectric structure has a first width extending along the second lateral direction; and
replacing a second portion of a second one of the epitaxial structures with a second dielectric structure, wherein the second dielectric structure has a second width extending along the second lateral direction, and wherein the second width is different from the first width.

19. The method of claim 18, further comprising:
forming an interconnect structure extending along the first lateral direction, the interconnect structure being physically coupled to the first dielectric structure and a remaining portion of the first epitaxial structure, and physically coupled to the second dielectric structure and a remaining portion of the second epitaxial structure;
wherein the interconnect structure is operatively configured as a bit line or a power rail carrying a ground voltage.

20. The method of claim 18, wherein the first epitaxial structure operatively forms a first read only memory (ROM) cell which presents a first logic state, and the second epitaxial structure operatively forms a second ROM cell which presents a second logic state different from the first logic state.
